(19) United States
(12) Patent Application Publication
(10) Pub. No.: US 2025/0279141 A1
(43) Pub. Date: Sep. 4, 2025

(54) OPTICAL QUATERNARY CONTENT-ADDRESSABLE MEMORY AND ITS OPTICAL COMPUTING APPLICATIONS

(71) Applicant: HEWLETT PACKARD ENTERPRISE DEVELOPMENT LP, Spring, TX (US)

(72) Inventors: YANIR LONDON, Spring, TX (US); LUCA BUONANNO, Spring, TX (US); GIACOMO PEDRETTI, Cernusco sul Naviglio (MI) (IT); THOMAS VAN VAERENBERGH, Diegem (BE)

(21) Appl. No.: 18/915,800

(22) Filed: Oct. 15, 2024

Related U.S. Application Data
(60) Provisional application No. 63/559,378, filed on Feb. 29, 2024.

(51) Int. Cl. G11C 15/00

(52) U.S. Cl. CPC G11C 15/00

(57) ABSTRACT

Systems and methods are provided for devices and methods for implementing fully optical quaternary content addressable memory (O-QCAM). In examples, the O-QCAM includes a search input configured to convert a multi-wavelength input signal encoded with a search word into a plurality of search optical signals; a plurality of QCAM word entries, each QCAM word entry comprising a plurality of O-QCAM cells; and a plurality of photodetectors, each photodetector optically coupled to a results end of a respective output match waveguide of an QCAM word entry. Each O-QCAM cell can be configured to store a reject value and one or more of a logic ‘0’, a logic ‘1’, and a wildcard value.

### CROSS REFERENCE TO RELATED APPLICATIONS

This application claims the benefit of and priority to U.S. Provisional Patent Application No. 63/559,378, filed on Feb. 29, 2024, the contents of which are incorporated herein by reference in their entirety.

### BACKGROUND

Content addressable memory (CAM) is a type of memory that can perform a search operation in which a data string may be input as search content and the resulting output is an address of a location in the memory that stores matching data. This is in contrast to a read operation, in which an address is input and the resulting output is the data stored in the memory location corresponding to the searched address. Certain CAMs may be able to perform both the aforementioned search operation and the aforementioned read operation, while non-CAM memories may be able to perform the read operation but not the search operation.

Ternary CAM (TCAM) is a type of CAM in which the bit cells can store a wildcard data value in addition to two binary data values. When a bit cell that stores the wildcard value is searched, the result is a match regardless of what search criterion is used to search the bit cell. Certain TCAMs may also allow a search to be conducted on the basis of a wildcard search criterion. When a bit cell is searched based on the wildcard search criterion, the result is a match regardless of what value is stored in the bit cell.

### BRIEF DESCRIPTION OF THE DRAWINGS

The present disclosure, in accordance with one or more various examples, is described in detail with reference to the following figures. The figures are provided for purposes of illustration only and merely depict typical, non-limiting aspects of such examples.

FIG. 1 illustrates an example optical search engine in accordance with examples of the present disclosure.

FIGS. 2A and 2B illustrate an example optical search engine in accordance an example of the present disclosure.

FIGS. 3A and 3B illustrate an example optical search engine in accordance another example of the present disclosure.

FIGS. 4A and 4B illustrate an example optical search engine in accordance yet another example of the present disclosure.

FIGS. 5A and 5B illustrate an example optical search engine in accordance another example of the present disclosure.

FIG. 6 illustrates an example computing device in accordance with examples of the technology disclosed herein.

FIG. 7 depicts a schematic representation of an example Boolean constrain propagation function that can be executed in accordance with examples of the present disclosure.

FIG. 8 depicts an example Boolean function that can be executed in accordance with examples of the present disclosure.

FIG. 9 is an example computing component that may be used to implement various features of optical search engines in accordance with the implementations disclosed herein

FIG. 10 is a computing component that may be used to implement examples of the disclosed technology.

The figures are not exhaustive and do not limit the present disclosure to the precise form disclosed.

### DETAILED DESCRIPTION

Content addressable memory (CAM) is a type of memory generally used in high-speed search applications. CAMs comprise hardware that compares an input pattern against stored binary data. The stored data of a CAM is not accessed by its location, but rather access is performed based on its content. A search word is input to the CAM, the CAM searches for the search word in its contents, and, when found, the CAM returns the address of the location where the found contents reside. CAMs are powerful, efficient, and fast. The input patterns and data in CAMs are represented by logic ‘0’s and logic ‘1’s (generally referred to as a binary CAM or bCAM).

Quaternary CAM (QCAM) goes beyond the binary nature of bCAM, allowing for the storage and searching for a third value, referred to as a wildcard or “don't care” symbol, and a fourth value, referred to as a reject or “always care” symbol. In examples disclosed herein, the wildcard symbol may be represented as “X” and reject symbol may be represented as “p.” A stored wildcard symbol can be treated like a match, regardless of whether the search criterion for the symbol of the stored data word is a logic ‘0’ or a logic ‘1.’ A stored reject symbol can be treated like a mismatch, regardless of whether the search criterion for the symbol of the stored data word is a logic ‘0’ or a logic ‘1.’ In this way, QCAMs allow for additional complexity as the input pattern can represent a range of patterns rather than only one pattern. As an illustrative example, an input pattern of “01XX0” could indicate a match for four separate stored words: 01000; 01010; 01100; and 01110, while an input pattern of “01ρρ0” could indicate a mismatch for any pattern that does not contain an “X” as the third and fourth symbol, and the rest of the pattern can return a match.

QCAMs can perform in-memory comparison operation in a massively parallel way, enabling extremely high throughput with a smaller footprint (e.g., reduced cell count) as compared to prior approaches. For example, the number of cells (n) for computing applications can be significantly lower as compared to bCAMs, as well as ternary CAMs (TCAMs). For instance, equality checks with CAMs or TCAMs can be performed for 2ⁿ items, while QCAMs can check up to

$$( \begin{matrix}2 n \\ n\end{matrix} )$$

items. Similarly, in the case of Boolean functions, bCAMs and TCAMs can be implemented to perform a Boolean function having an input space of 1:n cells, while a QCAM can be implemented to perform a Boolean function having an input space of 1:2n cells. As used herein, a “cell” may refer to structure that can be implemented to store a symbol value, such as logic ‘0’, logic ‘1’, ‘X’ (a wildcard value or “don't care” symbol), or ‘ρ’ (a reject value or “always care” symbol). Each symbol value may be stored at one or more bit positions. This increase in throughput can enable Internet packet routing, real-time network traffic monitoring, and more efficient access control lists, among other improvements in applications requiring fast memory comparisons.

Increasingly, data transfer is performed using optical communication technologies. Transferring data using optics enables extremely higher bandwidth compared to traditional data transfer electronically. Although applications are frequently using integrated optics to transfer data, existing CAM implementations usually require electronic signals. Accordingly, costly optical to electrical conversions may be required to convert the data from the optical to the electrical domain. Existing CAM implementations can increasingly become bottlenecks due to the need for these conversions, reducing the overall efficiency and throughput possible within a network. Thus, the reduced number of cells used to implement a CAM, such as in the case of a QCAM, can provide improved throughput and reduced bottlenecks.

Examples of the technology disclosed herein provide systems and methods for implementing QCAMs in the optical domain with full quaternary search capabilities. In various examples, an optical-QCAM (referred to herein as an O-QCAM) includes a plurality of word rows, each row comprising a plurality of O-QCAM cells. Each O-QCAM cell can store a symbol at one or more positions within a stored word and can store one of four values: logic ‘0’, logic ‘1’, ‘X’ (a wildcard value or “don't care” symbol), or ‘ρ’ (a reject value or “always care” symbol). Each cell can comprise one or more modulators arranged in one or more data rows. The symbol values can be stored in the optical domain using the one or more modulators tuned to pass or block a given wavelength of an input signal. Each bit position of the search word can be associated with one or more wavelengths of a multi wavelength input signal in some examples, and storing the word in the O-QCAM can comprise tuning the modulators to either pass or block according to an encoding scheme.

In various examples, the search word can be encoded on a multi-wavelength input signal, and a copy of the encoded signal can be coupled to each of the data rows of the O-QCAM cell. In various examples, an O-QCAM can comprise an optical search engine configured to store one or more QCAM stored words (also referred to herein as QCAM word entries). In various examples, a search word can be encoded using a single wavelength, with the value at each bit position encoded in the amplitude at that wavelength. In other examples, a search word can be encoded using a plurality of wavelengths, with the value at each bit position encoded in the amplitude of one of the wavelengths. In various examples, the optical search engine can comprise a hardware matrix multiplier comprising a plurality of multipath modulators configured to apply a matrix multiplication to an input signal encoded with a search word. In some examples, the optical search engine comprises a bank of QCAM stored words, wherein each QCAM stored word comprises a plurality of O-QCAM cells. Each bit position of a search word can be encoded on one or more wavelengths, and each bit position can be mapped to two input signals, in some examples. Based on the input waveguide on which an amplitude is detected, the optical search engine can indicate a match or mismatch between bits of the TCAM stored word and the search word.

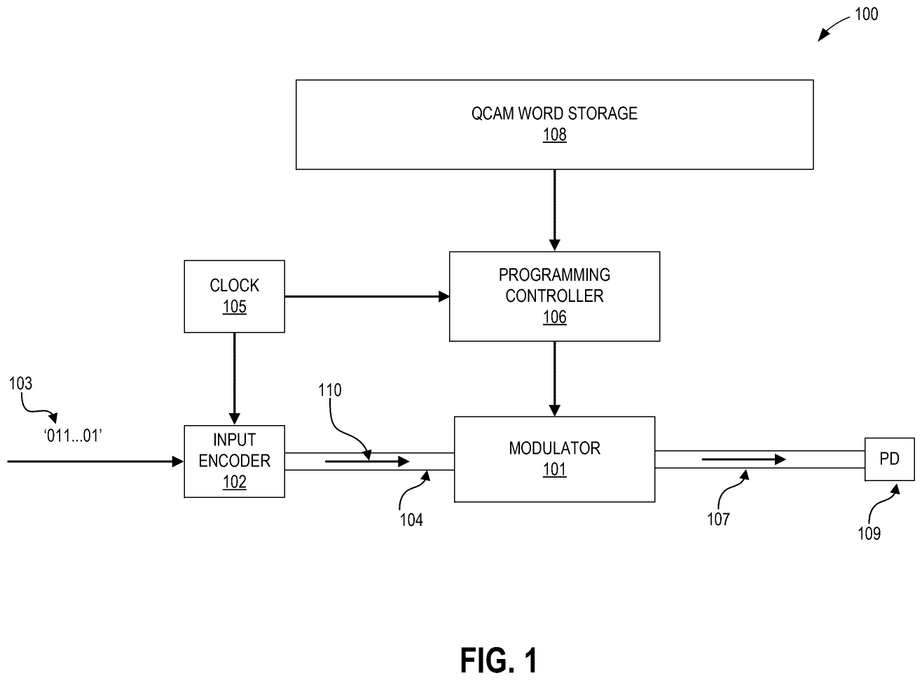

FIG. 1 illustrates an example optical search engine 100 in accordance with examples of the present disclosure. The optical search engine 100 is provided for illustrative purposes only and should not be interpreted as limiting the scope of the disclosed technology to only the depicted example. For ease of discussion, the optical search engine 100 of FIG. 1 is discussed with respect to comparison of one search word and one QCAM stored word through the use of a modulator 101, but in various examples the optical search engine 100 can include a plurality of modulators 101 associated with a plurality of QCAM stored words to enable comparison of a plurality of QCAM stored words against one or more search words. Furthermore, the optical search engine 100 can be used to compare a plurality of search words and one or more QCAM stored words.

As shown in FIG. 1, a search word 103 can be received by an input encoder 102. In various examples, the optical search engine 100 may include one or more input encoders 102, each input encoder 102 can be configured to encode a search word 103 of one or more received search words 103. In other examples, a single input encoder 102 may be configured to encode one or more search words 103. In some examples, an optical search engine input (not shown in FIG. 1) may be configured to receive the one or more search words 103 and transmit each received one or more search words to the input encoder 102. The one or more search words 103 may be received over an electrical connection (e.g., over an electrical trace), over an optical routing element (e.g., a waveguide, optical fiber), or a combination of both.

In various examples, the input encoder 102 may be configured to encode the one or more received search words 103 in the time domain (e.g., time division multiplexing (TDM), wavelength domain (e.g., wavelength division multiplexing (WDM)), or spatial domain (e.g., multiplexing over a spatial dimension). In various examples, the bits of a given search word 103 may be encoded on the same wavelength, for example, in the case of TDM. In this example, each search word 103 may be encoded on a distinct wavelength of a plurality of wavelengths. In other examples, such as WDM implementations, bits of a given search word 103 may be encoded on different wavelengths. In this case, each search word 103 may be encoded in the time domain (e.g., during different time slots). Table 1 illustrates an example encoding scheme in accordance with the technology disclosed herein.

TABLE 1

| | Encoded | Encoded |
|---|---|---|
| Search Word | Search Signal | Search Signal |
| Symbol (S) | Bit Value (s₁) | Bit Value (s₂) |
| 0 | 0 | A |
| 1 | A | 0 |
| X | 0 | 0 |
| ρ | A | A |

As shown in Table 1, each search word symbol S can be represented by two encoded search bit values s₁, s₂. To provide a search word symbol S of logic ‘1’, light having an amplitude A can be transmitted within the first encoded search bit value s₁ associated with the bit position and light having an amplitude of 0 can be transmitted within the second encoded search bit value s₂. For the search word symbol S of logic ‘0’, light having an amplitude of 0 can be transmitted as the first encoded search bit value s₁ associated with the bit position and light having an amplitude A can be transmitted as second encoded search bit value s₂. To provide a search word 103 of wildcard symbol ‘X’, light amplitude of 0 can be transmitted in both of the first encoded search bit value s₁ and the second encoded search bit value s₂. To provide the search word 103 as a reject symbol ‘ρ’, light having an amplitude A can be transmitted in both of the first encoded search bit value s₁ and the second encoded search bit value s₂.

In examples, a threshold amplitude A can be used to distinguish between light having an amplitude of 0 and light having an amplitude A. For example, light having an amplitude of 0 may refer to light having an amplitude that is less than the threshold amplitude A and, therefore, can be considered as having an amplitude of 0 (e.g., no light is transmitted or detected). In this case, the threshold amplitude A may be selected so to distinguish between light representing a logic “1” bit value from background noise, such that any light having an amplitude between A and 0 may be considered noise. Whereas, light having an amplitude of A may refer to light having an amplitude of at least A (e.g., equal to or above the threshold amplitude A). Thus, as an example, to provide a reject symbol ‘ρ’, light having an amplitude of equal to or above the threshold amplitude A can be transmitted in both of the first encoded search bit value s₁ and the second encoded search bit value s₂, while a wildcard symbol ‘X’ can be provided by light having an amplitude of less than the threshold amplitude A in both of first encoded search bit value s₁ and the second encoded search bit value s₂.

Although the examples herein are discussed with respect to the encoding scheme provided in Table 1, a person of ordinary skill in the art would understand that the assignment of light amplitude A and light of amplitude 0 in the associated encoded search bit values s₁, s₂ can be reversed in various examples. For example, the logical bit value ‘1’ could have an amplitude of 0 transmitted within the first encoded search bit value s₁ and transmit light having an amplitude A in the second encoded search bit value s₂. In some examples, the amplitude A may be the same value for each bit position, while in other examples at least one bit position may transmit light of a different amplitude A than at least one other bit position. In various examples, the amplitude A for each bit can decrease from a maximum amplitude A₀ for the first encoded search bit value s₁ to a minimum amplitude Aₙ for the nth encoded search bit value sₙ. In various examples, a more advanced amplitude scheme can be implemented, wherein the amplitude A for each encoded search bit value t can varying over a range of different amplitudes.

For ease of reference, the technology disclosed herein shall be described with respect to encoding of the search signal based on amplitude, but the encoding scheme can also be implemented based on different characteristics of light. As a non-limiting example, the input encoder 102 can be configured to encode the optical search signal using the polarization of the wavelength. For example, if the search word symbol S is a logic ‘1’, the encoding scheme could comprise light of a first polarization within the first encoded search bit value s₁ and light of a second polarization in the second encoded search bit value s₂, the reverse association for a logic ‘0’, and omitting light of the first polarization and the second polarization in both encoded search bit values s₁, s₂ to represent a wildcard symbol ‘X’. In various examples, the wildcard symbol ‘X’ can be represented by including light of either the first polarization or the second polarization in both encoded search bit values s₁, s₂. As another non-limiting example, the phase of light of the single wavelength can be used, with three different phases being utilized (two phases in combinations to represent logic ‘1’ and ‘0’, and a third phase for representing a wildcard ‘X’). In various examples, the wildcard symbol ‘X’ can be represented by including light of either the first phase or the second phase in both encoded search bit values s₁, s₂. The technology should not be interpreted as limited to encoding based on amplitude, but can also be implemented based on phase, fundamental mode profile, or other degrees of freedom of light. As a non-limiting example, different modes of light can be utilized to differentiate between logic values for the bits. A logic ‘1’ can be represented by having light of a first mode in the first encoded search bit value s₁ and light of a second mode in the second encoded search bit value s₂, a logic ‘0’ can be represented by light of a second mode in the first encoded search bit value s₁ and light of the first mode in the second encoded search bit value s₂, and the wildcard value can be represented by having light of a third mode in both the first encoded search bit value s₁ and the second encoded search bit value s₂. As another non-limiting example, the wildcard value can be represented by not having light in either the first mode or the second mode during both the first encoded search bit value s₁ and the second encoded search bit value s₂. In such examples, the one or more routing elements can be configured to propagate at least three modes of light.

In various examples, the encoded search signal 110 (also referred to herein as a search optical signal) can comprise 2n encoded search bit values, where n is the number of bit positions in the search word. As a non-limiting example, the search word 103 may comprise 8 bit positions, and the encoded search signal 110 can comprise 8 sets of associated encoded search bit values representing 8 symbols (i.e., 16 encoded search bit values in total). In some examples, each associated search word symbol S may comprise more than one encoded search signal bit value. As a non-limiting example, a first encoded search word symbol S₁ may comprise two encoded search signal bit values s₁₋₁, s₂₋₁ and the second encoded search word symbol S₂ may comprise two encoded search signal bit values s₁₋₂, s₂₋₂. In various examples, the encoded search signal bit values s₁, s₂ associated with a bit position may be non-continuous (i.e., the encoded search signal bit values may be separated by one or more encoded search signal bit values not associated with the bit position). A key can be included to descramble the light signals at the photodetector 109.

The encoded search signal 110 generated by the input encoder 102 can be coupled to an input routing element 104. The input routing element 104 may comprise an optical waveguide, an optical fiber, or other optical routing medium known in the art. The input routing element may be made of, but not limited to, one or more of gallium arsenide (GaAs), indium phosphide (InP), silicon (Si), silicon nitride (SiN), LiNbO₃, glass, and silica, among other materials. In various examples, the input routing element 104 may be disposed in a silicon photonics assembly. One or more of the elements illustrated in FIG. 1 may be disposed in a silicon photonics assembly. The input routing element 104 can include one or more coupling components (not shown in FIG. 1) disposed at the first end to couple the encoded search signal 110 from the input encoder 102 and at the second end to couple the encoded search signal 110 into the modulator 101. In various examples, a plurality of input routing elements 104 may be included, each input routing element 104 configured to couple the encoded search signal 110 from the input encoder 102 to a modulator 101 of a plurality of modulators 101.

To perform a search operation, the modulator 101 can be modulated to represent a QCAM stored word, in some examples. In other examples, the modulator can be modulated to represent one or more QCAM stored words. In various examples, the modulator 101 may comprise one or more modulators, including but not limited to waveguide resonators (e.g., ring modulator), multipath interferometers (e.g. Mach Zehnder interferometer (MZI)), photonic crystals (e.g., lithium niobate (LiNbO₃)), phase shifters, polarization filters, lattice filters, or other modulator components capable of being driven by an electronic signal to tune the performance characteristics of the modulator 101.

In various examples, the optical search engine 100 can include a plurality of modulators 101. In some examples, each modulator 101 can be configured to compare a different QCAM stored word against the encoded search signal 110. In some examples, one or more modulators 101 may be configured in parallel, with a copy of the encoded search signal 110 optically coupled to an input of each of the one or more modulators 101. One or more modulators 101 may be connected in series in some examples, with the output of a first modulator 101 optically coupled to the input of a second modulator 101, the output of the second modulator 101 optically coupled to a third modulator 101, and so on.

In various examples, a programming controller 106 (also referred to as a driver) can be used to tune the one or more modulators 101 to represent the bit positions of the one or more QCAM stored words. In various examples, the programming controller 106 can be configured to control tuning of all of the modulators of the optical search engine, while in other examples a plurality of programming controllers 106 can be included, each of the plurality of programming controllers 106 configured to tune one or more modulators 101. Each modulator 101 can be communicatively coupled to one or more tuning components (not shown in FIG. 1), each of the one or more tuning components capable of changing an optical characteristic of the one or more modulators that make up the modulator 101 to enable tuning of the performance of the modulator 101. In various examples, the one or more tuning components can comprise one or more devices configured to change the refractive index of the core or cladding of the one or more modulators, control the number of free carriers, and/or create a red and/or blue shift of the resonance wavelength of the one or more modulators. Non-limiting examples of tuning components include heaters, electrical contacts, among other devices used to tune the resonance wavelength of optical components. In various examples, the programming controller 106 can comprise a processing component, a field programmable gate array (FPGA), an application specific integrated circuit (ASIC), or other type of processor present in computing systems. In some examples, the programming controller 106 can comprise a central processing unit (CPU), a graphics processing unit (GPU), or other processing component external to the optical search engine 100.

Each of the QCAM stored words can be maintained in a QCAM word storage 108 in various examples. The QCAM word storage 108 can comprise a non-transitory machine-readable storage medium configured to store one or more QCAM words. Non-limiting examples of the QCAM word storage 108 can comprise common forms of memory including RAM, PROM, EPROM, FLASH-EPROM, NVRAM, memristors, optical storage memories, among electrical, optical, or electro-optical storage medium. In various examples, the QCAM word storage 108 can comprise one or more types of volatile and/or non-volatile memory. In various examples, the QCAM word storage 108 may be a dedicated memory component for the optical search engine 100 configured to store QCAM stored words, while in other examples the QCAM word storage 108 can be a partition or other assigned space in a shared memory component. The QCAM word storage 108 may be implemented in a storage area network (SAN) or other networked storage solution. The programming controller 106 can be communicatively coupled to the QCAM word storage 108 and configured to retrieve a QCAM stored word to compare against the encoded stored word through the modulator 101. The programming controller 106 can maintain a mapping of QCAM stored words to the modulators 101 in a dedicated memory component of the programming controller 106 (not shown in FIG. 1), in the QCAM word storage 108, or in another separate memory component communicatively coupled to the optical search engine 100 (not shown in FIG. 1), or a combination thereof. In some examples, each QCAM word can be stored in the QCAM word storage 108 in its encoded state, while in other examples the QCAM words can be stored in an un-encoded state. When storing the QCAM stored word in the encoded state, the latency between retrieving the QCAM stored word and applying the associated drive signal by the programming controller 106 can be reduced, but the memory footprint of the QCAM word storage 108 may be larger than when the QCAM stored words are stored in an un-encoded state (since the size of the word is at least doubled in the encoded state to have a logic value for each encoded search bit value assigned to the bit position). The method of storage (encoded or un-encoded) depends on the requirements of the application in which the O-QCAM is implemented.

In performing an operation on the search word 103 encoded in accordance with Table 1, the programming controller 106 can be configured to tune the modulator 101 either to allow light of the wavelength of the encoded word or to block the light. Table 2 shows the operational state of the modulator 101 for each corresponding bit value of the QCAM stored word retrieved from the QCAM word storage 108.

TABLE 2

| QCAM Stored | Encode Stored | Encode Stored |
|---|---|---|
| Data Word | Data Bit | Data Bit |
| Symbol (D) | Value (d₁) | Value (d₂) |
| 1 | 0 (Block) | 1 (Pass) |
| 0 | 1 (Pass) | 0 (Block) |
| X | 0 (Block) | 0 (Block) |
| ρ | 1 (Pass) | 1 (Pass) |

As shown in Table 2, the modulator 101 can either be configured to “pass” light or “block” light based on an encoded stored data bit values d₁, d₂ corresponding to the bit position of the QCAM stored data symbol D. To represent an encoded stored data symbol of logic ‘1’, the modulator 101 can be tuned to block light at the encoded wavelength corresponding to the first encoded data bit value d₁ associated with the bit position and tuned to pass light at the encoded wavelength corresponding to the second encoded data bit value d₂. In various examples, “blocking” light can comprise removing light, attenuating light, or otherwise introducing optical loss at a given wavelength from a waveguide using one or more stop band or drop modulators, or through destructive interference of light at the given wavelength. “Blocking” light as used herein may refer to transmitting an amplitude of light that is less than an amplitude A and “passing” light as used herein may refer to transmitting an amplitude of light that is equal to or above the amplitude A, as described above. To represent a logic ‘0’, the modulator 101 can be tuned to pass light at the encoded wavelength corresponding to the first encoded data bit value d₁ associated with the bit position and tuned to block light at the encoded wavelength corresponding to the first encoded data bit value d₂. To represent a wildcard value ‘X’, the modulator 101 can be tuned to block light at the encoded wavelength for both encoded data bit values d₁, d₂ associated with the bit position. To represent a reject value ‘ρ’, the modulator 101 can be tuned to pass light at the encoded wavelength for both encoded data bit values d₁, d₂ associated with the bit position. In various examples, the programming controller 106 can be configured to apply a high-speed electrical signal to the one or more tuning components capable of changing the optical characteristics of the modulator 101 such that the modulator 101 can be configured in accordance with Table 2 during the encoded data bit values d₁, d₂.

Based on the logic states indicated in Tables 1 and 2, light will pass through the modulator 101 for an encoded search symbol S only when a mismatch occurs between the value of a bit position of the search word 103 and the corresponding value of the bit position of the QCAM stored word. Table 3 shows the results based on the encoded bit value on the optical search signal and of the corresponding modulator 101.

TABLE 3

| Search Word | QCAM Stored Word | Match/Mismatch |
|---|---|---|
| (s1, s2) | Symbol (d₁, d₂) | (passed/blocked) |
| 0 (0, A) | 0 (pass, block) | Match (blocked) |
| 0 (0, A) | 1 (block, pass) | Mismatch (passed) |
| 0 (0, A) | X (block, block) | Match (blocked) |
| 0 (0, A) | ρ (pass, pass) | Mismatch (passed) |
| 1 (A, 0) | 0 (pass, block) | Mismatch (passed) |
| 1 (A, 0) | 1 (block, pass) | Match (blocked) |
| 1 (A, 0) | X (block, block) | Match (blocked) |
| 1 (A, 0) | ρ (pass, pass) | Mismatch (passed) |
| X (0, 0) | 0 (pass, block) | Match (blocked) |
| X (0, 0) | 1 (block, pass) | Match (blocked) |
| X (0, 0) | X (block, block) | Match (blocked) |
| X (0, 0) | ρ (pass, pass) | Match (blocked) |
| ρ (A, A) | 0 (pass, block) | Mismatch (passed) |
| ρ (A, A) | 1 (block, pass) | Mismatch (passed) |
| ρ (A, A) | X (block, block) | Match (blocked) |
| ρ (A, A) | ρ (pass, pass) | Mismatch (passed) |

As shown in Table 3, when the symbol of the encoded search word is a logical ‘1’, the input (e.g., encoded optical search signal from the input encoder 102) includes light of at an encoded wavelength having an amplitude A (e.g., equal to or above a threshold amplitude A) representing the first encoded search bit value s₁ of the associated bit position and does not include light of the encoded wavelength during the representing the second encoded search bit value s₂ (e.g., light on the input routing element 104 having an amplitude below a threshold amplitude A). If the bit value of the QCAM stored word at the corresponding bit position is also a logic ‘1’, the modulator 101 can be driven to tune the modulator 101 to block light of the encoded wavelength representing the first encoded search signal bit value s₁ and pass light of the encoded wavelength during the second representing the second encoded search signal bit value s₂. Therefore, because the modulator 101 is configured to block light of the encoded wavelength for the first encoded search signal bit value s₁, the light on the input routing element 104 is not permitted to pass through the modulator 101 and into an output routing element 107 (e.g., light at the output routing element 107 is below the threshold amplitude A). And, because there is no light on the input routing element 104 representing the second encoded search bit value s₂, light at the output routing element 107 is below the threshold amplitude A (e.g., no light passes) even though it is configured to pass light because the light on the input routing element 104 representing the second encoded search bit value s₂ is below the threshold amplitude A. Accordingly, the lack of light on the output routing element 107 indicates that the symbols of the search word 103 and the QCAM stored word at the respective bit position are matched.

When the symbol of the encoded word is a logical ‘0’, the input (encoded optical search signal from the input encoder 102) does not include light of an encoded wavelength representing the first encoded search bit value s₁ (e.g., light on the input routing element 104 having an amplitude below a threshold amplitude A) of the associated bit position and does include light of the single wavelength having an amplitude A (e.g., equal to or above a threshold amplitude A) representing the second encoded search bit value s₂. If the symbol of the QCAM stored word at the corresponding bit position is also a logic ‘0’, the modulator 101 would be driven such that the modulator 101 is tuned to pass light of the encoded wavelength representing the first encoded search bit value s₁ and block light of the encoded wavelength representing the second encoded search bit value s₂. Therefore, because the modulator 101 is configured to pass light of the single wavelength representing the first encoded search bit value s₁, no light (e.g., light having an amplitude below the threshold amplitude A) would pass through the modulator 101 and into the output routing element 107 (because light of the encoded wavelength included in the signal representing the first encoded search bit value s₁ is below the threshold amplitude A). And, because the modulator 101 is configured to block light of the encoded wavelength representing the second encoded search bit value s₂, the light on the input routing element 104 is not permitted to pass (e.g., attenuated) through the modulator 101 and into an output routing element 107. Accordingly, the lack of light on the output routing element 107 indicates that the symbols of the search word 103 and the QCAM stored word at the respective bit position are matched.

In addition, if the symbol of the bit position of the QCAM stored word is a reject value ‘ρ’, regardless of whether the input is a logic ‘1’ or ‘0’, light is present on the output routing element 107 (e.g., the light has an amplitude equal to or above the threshold amplitude A). To represent the reject value ‘ρ, the modulator 101 is driven by the programming controller 106 to pass light of the encoded wavelength on which the search word 103 is encoded representing the first and second encoded search bit values s₁, s₂. Therefore, a mismatch is indicated for that bit position whenever light is on the input routing element 104, which is permitted to pass through the modulator 101 and into an output routing element 107. Similarly, if the search word 103 included a reject value ‘ρ’ at a bit position, a mismatch would be indicated regardless of whether the input is a logic ‘1’ or ‘0’, because light would be present on the input routing element 104 (e.g., light having an amplitude equal to or above the threshold amplitude A), and therefore light (e.g., light having an amplitude equal to or above than the threshold amplitude A) would pass the modulator 101 onto the output routing element 107.

If the symbol of the bit position of the QCAM stored word is a wildcard value ‘X’, regardless of whether the input is a logic ‘1’ or ‘0’ or a reject value ‘ρ’, no light is present on the output routing element 107 (e.g., the light has an amplitude less than the threshold amplitude A). To represent the wildcard value ‘X’, the modulator 101 is driven by the programming controller 106 to block light of the encoded wavelength representing the first and second encoded search bit values s₁, s₂. Therefore, a match is always indicated for that bit position, regardless of the value at the corresponding bit position of the search word 103. Similarly, if the search word 103 included a wildcard value ‘X’ at a bit position, a match would always be indicated regardless of the associated bit value at the bit position in the QCAM stored word because no light would be on the input routing element 104 (e.g., light having an amplitude less than the threshold amplitude A), and therefore no light (e.g., light having an amplitude less than the threshold amplitude A) would pass the modulator 101 onto the output routing element 107.

A mismatch at a given bit position can be indicated by the presence of light on the output routing element 107 (e.g., equal to above a threshold amplitude A). As seen in Table 3, when the bit position of the input is a logic ‘1’ but the bit position of the QCAM stored word is a logic ‘0’ light is passed to the output routing element 107 representing the first encoded search bit value s₁. The modulator 101 is configured to pass light of the single wavelength and the input includes light having an amplitude A (e.g., least an amplitude A) of the single wavelength on the input routing element 104 representing the first encoded search bit value s₁. Therefore, the light would pass through the modulator 101 to the output routing element 107. Where the bit values are reversed, light would be on the output routing element 107 representing the second encoded search bit value s₂, indicating the mismatch between the search word 103 and the QCAM search word at the respective bit position.

In various examples, the encoding of the input search word 103 can be performed in accordance with a clock (CLK) signal from clock 105. The CLK signal can be used to identify each of the encoded search bit values s₁, s₂ associated with each respective bit position of the search word 103. In various examples, the CLK signal from clock 105 can also be used by the programming controller 106 to generate the drive signal used to configure the modulator 101 to represent the QCAM stored word. In some examples, the programming controller 106 can include one or more circuits to delay the CLK signal from clock 105 such that the programming controller 106 applies the drive signal in sync with the encoded search signal 110 as it is optically coupled into the modulator 101. In some examples, a second CLK signal (different from the CLK signal used by the input encoder 102) can be sent to the programming controller 106 from the same clock 105 or a different clock source.

As seen in FIG. 1, a photodetector 109 can be optically coupled to a result end of the output routing element 107 in various examples. The photodetector 109 can be configured to sense the amplitude of light present on the output routing element 107, thereby detecting the mismatch and/or match for the respective bit position. In various examples, the photodetector 109 can comprise a photodiode or other type of circuit-type detector of photons. In various examples, each photodetector 109 can include circuitry configured to output a memory address corresponding to the stored word represented by the modulator 101. In some examples, each photodetector 109 can output a match/mismatch indication to an encoder circuit (not shown in FIG. 1) configured to generate the memory address corresponding to the stored word of the modulator 101 for which a match indication is received from a photodetector 109. In some examples, each photodetector 109 may send the indication to a processing circuit within the optical search engine 100 (not shown in FIG. 1) being configured to identify the memory address associated with the specific QCAM stored word represented by the modulator 101 and output an electrical signal to a memory controller or other device controller access to the memory storage.

In various examples, the photodetector 109 can be configured to integrate the mismatches during a search cycle of the search word 103 (i.e., over the 2n encoded search bit values s), enabling the photodetector 109 to determine the sum of all mismatches between the search word 103 and the QCAM stored word represented by the modulator 101. In various examples, the photodetector 109 can include circuitry configured to perform the integration of light for the duration of the search cycle, while in some examples the photodetector 109 can be configured with a long time-constant (TC) to enable integration to occur within the photodetector 109. In some examples, the photodetector 109 can be configured to flag or otherwise identify at which bit positions a mismatch occurred.

Although a single modulator 101 is illustrated in FIG. 1, in various examples the optical search engine 100 can comprise a plurality of modulators 101, each modulator 101 configured to represent a different QCAM stored word, or modulator 101 can be configured to represent a plurality of QCAM stored words. In this way, a plurality of stored words can be compared against the search word 103 during the same search operation.

In some examples, optical search engine 100 may be configured to perform a TDM QCAM. For example, the input encoder 102 may be configured to encode a received search word 103 in the time domain. In this case, the bits of each of the one or more search words 103 may be encoded during different time slots. In some examples, a plurality of search words 103 may be encoded by encoding each search word using a different encoding wavelength and the bits of the search words may be encoded during different time slots. In this case, one or more bits of each respective search word may be encoded in common time intervals. For example, a first bit from each of the plurality of search words may be encoded during a first time slot, while a second bit from each of the plurality of search words may be encoded during a second time slot, and so on.

Referring to Table 1, with reference to a single search word 103 as an illustrative example, encoded search bit values s₁, s₂ can be encoded during two time slots t₁, t₂, respectively. For example, to provide a search word symbol of logic ‘1’, light having an amplitude A can be transmitted within the first time slot t₁ (e.g., to represent encoded search bit values s₁) associated with the bit position and light amplitude of approximately 0 can be transmitted within the second time slot t₂ (e.g., to represent encoded search bit values s₂). In various examples, the time slots t₁, t₂ associated with a bit position may comprise consecutive time slots, while in other examples the associated time slots t₁, t₂ with a bit position may comprise non-consecutive time slots. In various examples, the encoded search signal 110 can comprise 2n time slots, where n is the number of bit positions in the search word.

To perform a TDM search operation, the modulator 101 can be modulated in time to represent a QCAM stored word, according to the encoding scheme shown in Table 2 above. For example, the programming controller 106 can be configured to tune the modulator 101 either to allow light of the wavelength of the encoded word or to block the light during a time slot. Thus, the modulator 101 can either be configured to pass light or block light within the time slots t associated with the bit position of the QCAM stored word bit value. For example, to represent a logic ‘1’, the modulator 101 can be tuned to block light at the encoded wavelength during the first time slot t₁ associated with the bit position and tuned to pass light at the encoded wavelength during the second time slot t₂. To represent a logic ‘0’, the modulator 101 can be tuned to pass light at the encoded wavelength during the first time slot t₁ associated with the bit position and tuned to block light at the encoded wavelength during the second time slot t₂. To represent a wildcard value ‘X’, the modulator 101 can be tuned to block light at the encoded wavelength during both time slots t₁, t₂ associated with the bit position. To represent a reject value ‘ρ’, the modulator 101 can be tuned to pass light at the encoded wavelength during both time slots t₁, t₂ associated with the bit position.

To encode a plurality of search words 103, encoded search bit values s₁, s₂ of each search word 103 can be encoded during two time slots t₁, t₂, respectively, using different wavelengths for each search word 103. The modulator 101 can either be configured to pass light or block light within the time slots t associated with the bit position of the QCAM stored word bit value at the encoded wavelengths.

Using the encoding scheme discussed above, the optical search engine 100 can be configured to provide full optical quaternary search functionality through TDM encoding. In this way, the optical-to-electrical conversions can be avoided and the search can be performed faster. Utilizing the TDM encoding makes the optical search engine 100 more compatible with current photonics capabilities by reducing the need for optical buffers, reducing the latency in the system. Encoding in the time domain further enables each QCAM stored word to be represented with a single modulator 101 (which may comprise one or more optical elements (e.g., rings, MZIs, photonic crystals, etc.)), reducing the footprint of the optical search engine 100 and enabling more QCAM stored words to be compared against an input search word. Based on the logic states indicated in Tables 1 and 2, light will pass through the modulator 101 during a given time slot t only when a mismatch occurs between the value of the bit position of the search word 103 and the corresponding value of the bit position of the QCAM stored word, as set forth in Table 3 above.

In various examples, the photodetector 109 can be configured to integrate the mismatches over time for the duration of the search word 103 (i.e., for the duration of the 2n time slots t), enabling the photodetector 109 to determine the sum of all mismatches between the search word 103 and the QCAM stored word represented by the modulator 101. In this way, the degree of mismatch between the search word 103 and the respective QCAM stored word.

U.S. Pat. No. 11,200,929, the disclosure of which is incorporated herein by reference in its entirety, provides examples optical search engines implemented for TDM-based optical TCAM. The optical search engines disclosed therein may be extended to the presently disclosed technology so to implement the encoding schemes as described above.

In some examples, optical search engine 100 may be configured to perform a WDM O-QCAM. For example, the input encoder 102 may be configured to encode a received search word 103 in the wavelength domain. In this case, each bit of a search word 103 may be encoded using different wavelengths of light. In some examples, a plurality of search words 103 may be encoded using different time slots. For example, the bits of each search word may be encoded using different wavelengths during a respective time slot designated for a given search word. For example, the bits of a first search word may be encoded during a first time slot using different wavelengths to encode each bit, while bits of another search word maybe encoded during a second time slot using the different wavelengths.

Referring to Table 1, encoded search bit values s₁, s₂ can be encoded using two wavelengths of light λ₁, λ₂, respectively. For example, to provide a search word symbol of logic ‘1’, light having an amplitude A can be transmitted using a first wavelength λ₁ (e.g., to represent encoded search bit values s₁) associated with the bit position and light amplitude of approximately 0 can be transmitted using a second wavelength λ₂ (e.g., to represent encoded search bit values s₂). In various examples, the encoded search signal 110 can comprise 2n wavelengths, where 2n is the number of bit positions in the search word and n is the number of symbols.

To perform a WDM search operation, the modulator 101 can be modulated in the wavelength domain to represent a QCAM stored word, according to the encoding scheme shown in Table 2 above. For example, the programming controller 106 can be configured to tune the modulator 101 either to allow light of the respective wavelength of the encoded word or to block the light of the respective wavelength. Thus, the modulator 101 can either be configured to pass light or block light for a given wavelength λ associated with the bit position of the QCAM stored word bit value. For example, to represent a logic ‘1’, the modulator 101 can be tuned to block light at the first wavelength λ₁ associated with the bit position and tuned to pass light at the second wavelength λ₂. To represent a logic ‘0’, the modulator 101 can be tuned to pass light at the first wavelength λ₁ associated with the bit position and tuned to block light at the encoded the second wavelength λ₂. To represent a wildcard value ‘X’, the modulator 101 can be tuned to block light at using both wavelengths λ₁, λ₂ associated with the bit position. To represent a reject value ‘ρ’, the modulator 101 can be tuned to pass light using both wavelengths λ₁, λ₂ associated with the bit position.

Using the encoding scheme discussed above, the optical search engine 100 can be configured to provide full optical quaternary search functionality through WDM encoding. In this way, the optical-to-electrical conversions can be avoided and the search can be performed faster. Utilizing the WDM encoding makes the optical search engine 100 more compatible with current photonics capabilities by reducing the need for optical buffers, reducing the latency in the system. Encoding in the wavelength domain further enables each QCAM stored word to be represented with a single modulator 101 (which may comprise one or more optical elements (e.g., rings, MZIs, photonic crystals, etc.)), reducing the footprint of the optical search engine 100 and enabling more QCAM stored words to be compared against an input search word. Additionally, encoding in the wavelength domain can enable processing a single search word within a single search cycle, thereby reducing latency.

In various examples, the photodetector 109 can be configured to integrate the mismatches by aggregating detected light for a search word 103, enabling the photodetector 109 to determine the sum of all mismatches between the search word 103 and the QCAM stored word represented by the modulator 101. In this way, the degree of mismatch between the search word 103 and the respective QCAM stored word.

U.S. Pat. No. 11,057,143, the disclosure of which is incorporated herein by reference in its entirety, provides examples optical search engines implemented for WDM-based optical TCAM. The optical search engines disclosed therein may be extended to the presently disclosed technology so to implement the encoding schemes as described above.

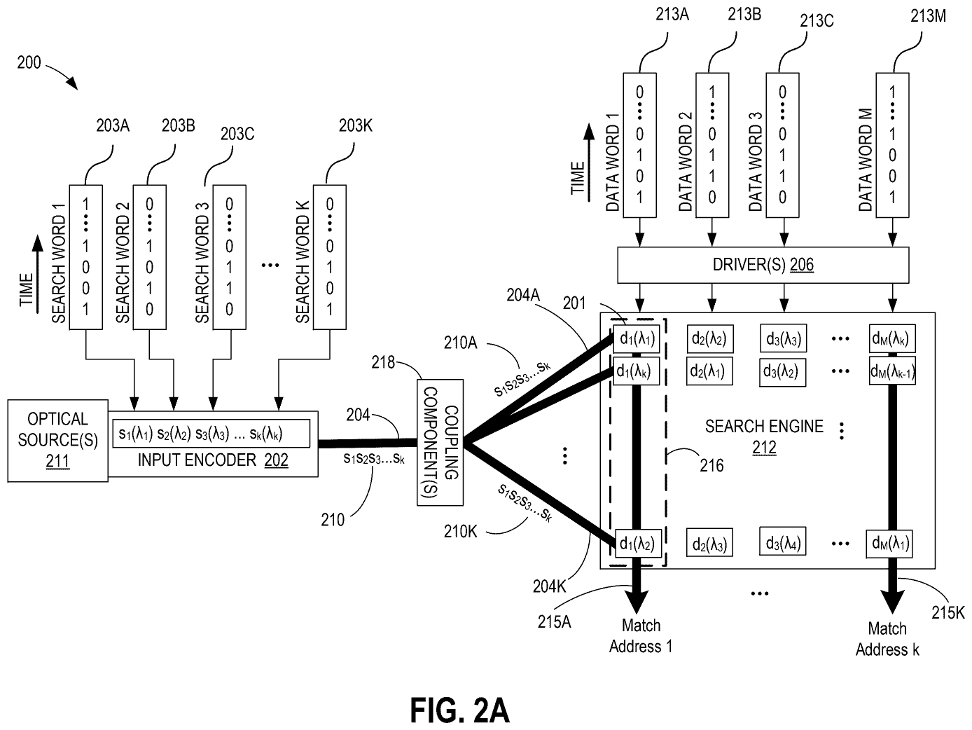

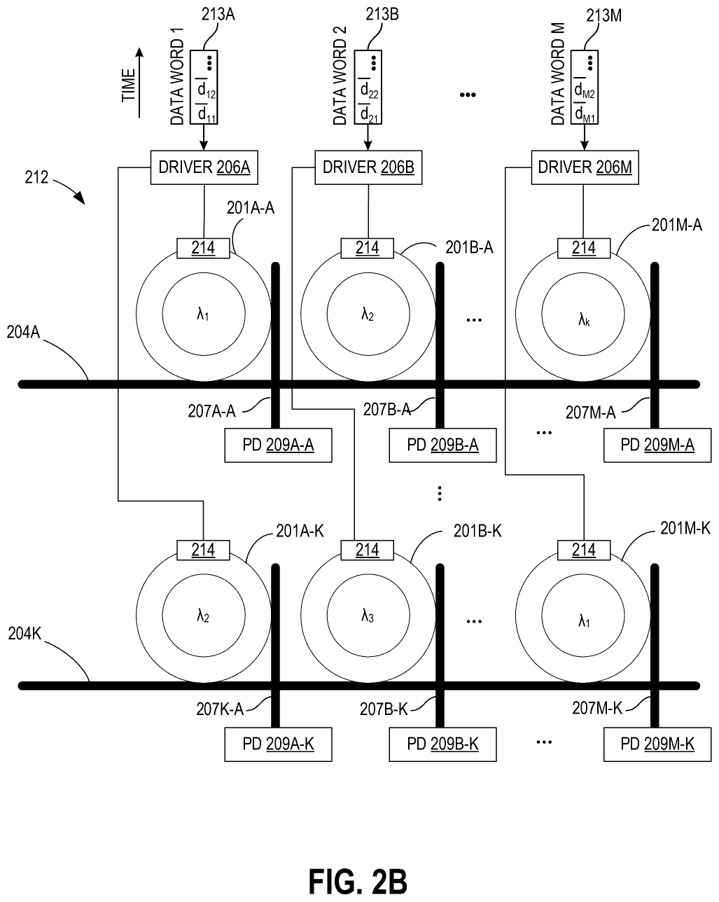

FIG. 2A an example optical search engine 200 in accordance an example of the present disclosure. The optical search engine 200, in this example, may be implemented to perform TDM O-QCAM in accordance with the examples herein. The optical search engine 200 is provided for illustrative purposes only and should not be interpreted as limiting the scope of the disclosed technology to only the depicted example. In examples, optical search engine 200 may be implemented to compare a number of K search words, each having a number of L bits, and a number M QCAM stored words, each having a number of L bits. In various examples, optical search engine 200 performs the comparison optically executing matrix multiplication, for example, multiplying a K×L matrix representing the search words with an M×L matrix representing QCAM words that are stored in a memory, such as QCAM word storage 108 of FIG. 1.

As shown in FIG. 2A, a plurality of search words 203A-203K (collectively referred to herein as search words 203) can be received an input encoder 202. The input encoder 202 may be substantially similar to input encoder 102 described above in connection with FIG. 1. For example, search words 203A-203K can be encoded by the input encoder 202 by modulating input optical signals provided by one or more optical source(s) 211 to generate an encoded search signal 210, similar to the encoding discussed with respect to FIG. 1. In various examples, the optical source(s) 211 can comprise one or more types of light emitting diodes (LEDs; potentially with subsequent narrow-band filters), multi-wavelength lasers (e.g., comb lasers), vertical cavity surface emitting lasers (VCSELs), or other light emission sources. In various examples, the optical source(s) 211 can be communicatively coupled to the input encoder 202 so that the input encoder 202 can encode the search words 203 on one or more optical signals of multiple wavelengths of light emitted by the optical source(s) 211. In some examples, input encoder 202 may be implemented using modulators to encode input light from optical source(s) 211 with the bits of the search words 203, for example, by modulating an optical power.

The input encoder 202 may be configured to encode the search words 203 in the time domain. In various examples, each of the search words 203 may be encoded using a different encoding wavelength (e.g., K different wavelengths), while the bits of each search word 203 may be encoded during different time slots according to encoding scheme described in Table 1 discussed above in connection with FIG. 1. For example, as shown in FIG. 2A, bits of search word 203A can be encoded on first wavelength λ₁, bits of search word 203B can be encoded on second wavelength λ₂, and so on until search word 203K can be encoded on a kth wavelength AK, and encoded search bit values s₁, s₂ of each search word 203 can be encoded during two time slots t₁, t₂, respectively. In some examples, input encoder 202 may be implemented using modulators to tune an amplitude of the optical signal at each wavelength according to the encoding scheme.

The encoded search signal 210 generated by the input encoder 202 can be coupled to an input routing element 204. Input routing element 204 may be an example implementation of input routing element 104 of FIG. 1. The input routing element 204 can include one or more coupling components 218 disposed at the first end to couple the encoded search signals 203 from the input encoder 202 and at the second end to into a search engine 212. In the example of FIG. 2A, the input routing element 204 is coupled to a 1×K optical splitter as an example coupling components 218, which splits the encoded search signal 203 on the input routing element 204 into multiple copies of the encoded search signal encoded search signal 210A-210K.

In some examples, optical source(s) 211 may comprise multiple sources (e.g., a number G of optical sources) that supply multiple input optical signals to the input encoder 202. In this case, the input encoder 202 may generate a number G of encoded search signals, each of which may be identical to encoded search signal 210. The G encoded search signals may be input into G input routing elements each of which may include a coupling component. The coupling component, in this example, may be a 1×K/G splitter, each of which may split a respective encoded search signal into K copies of encoded search signal 210A-210K that that are coupled to the search engine 212 via input routing elements 204A-204K. This example may be useful where power budget restricts the amount of power that can be supplied to a single optical source 211. Thus, multiple optical sources 211 can be used to address power budget limitations.

To perform a TDM search operation, the search engine 212 can be modulated in time to represent a plurality of QCAM stored words 213A-213M. In various examples, the search engine 212 comprises a plurality of modulators 201, each of which may be implemented as modulator 101 of FIG. 1. In an illustrative example, each modulator 201 may be a waveguide resonator (e.g., ring modulator) or other modulator component capable of being driven by an electronic signal to tune the performance characteristics of the modulators 201. In the example of FIG. 2A, the search engine 212 comprises an M×K array of modulators 201. For ease of illustration, only one modulator 201 is labeled with a reference number as an illustrative example.

The plurality of modulators may be tuned through operation of one or more driver(s) 206 (e.g., programming controller 106 of FIG. 1) to represent bit positions of the QCAM stored words 213A-213M. The driver(s) 206 may be configured to encode the QCAM stored words 213A-213M into the plurality of modulators in the time domain. For example, driver(s) 206 may receive bits of each QCAM stored word 213A-213M from a memory (e.g., QCAM word storage 108 of FIG. 1) associated with different time slots and may be operated, during each respective time slot, to tune the plurality of modulators so to represent each bit of the QCAM stored word 213A-213M during the different time slots. In this case, the entirety of each QCAM stored word 213A-213M may not be stored in the optical search engine 212. Instead, bits of each QCAM stored word 213A-213M can be retrieved from memory (e.g., QCAM word storage 108 of FIG. 1) and used by driver(s) 206 to store different bits of each QCAM stored word 213A-213M during different time slots. Each modulator 201 can be communicatively coupled to one or more tuning components, which can tuned by driver(s) 206. Each of the one or more tuning components may be capable of changing an optical characteristic of the one or more modulators that make up each modulator 201 to enable tuning of the performance of the modulator 201. In various examples, the one or more tuning components can comprise one or more devices configured to change the refractive index of the core or cladding of the one or more modulators, control the number of free carriers, and/or create a red and/or blue shift of the resonance wavelength of the one or more modulators. Non-limiting examples of tuning components include heaters, electrical contacts, among other devices used to tune the resonance wavelength of optical components.

FIG. 2B illustrates an example implementation of search engine 212 in which the modulators are implemented as waveguide resonators. In the example of FIG. 2B, search engine 212 comprises waveguide resonators 201A-A through 201M-K coupled to input routing element 204A-204K, as described in connection with FIG. 2B. The waveguide resonators 201A-A through 201M-K are arranged in rows. For example, as shown in FIG. 2B, waveguide resonators 201A-A through 201M-A are coupled to input routing element 204A and waveguide resonators 201A-K through 201M-K are coupled to input routing element 204K. The waveguide resonators 201A-A through 201M-K are designed for a plurality of resonance frequencies (e.g., λ₁ through λₖ), such that each row comprises one waveguide resonator of each resonance frequency and each column comprises one waveguide resonator of each resonance frequency.

The plurality of waveguide resonators 201A-A through 201M-K may be tuned through operation of driver(s) 206 (shown in FIG. 2B as driver(s) 206A through 206M) to represent bit positions of the QCAM stored words 213A-213M. Each waveguide resonator 201A-A through 201M-K can be communicatively coupled to one or more tuning components 214 capable of changing an optical characteristic of the waveguide resonator 201A-A through 201M-K. In various examples, the one or more tuning components can comprise one or more devices configured to change the refractive index of the waveguide resonators 201A-A through 201M-K that causes a shift of the resonance frequency. A shift in the resonance frequency can result in blocking an input optical signal that propagates at the un-shifted resonance frequency. For example, waveguide resonator 201A-A can have a resonance frequency corresponding to λ₁ (e.g., speed of light divided by λ₁), which can pass light at λ₁ from the input routing element 204A to a drop routing element 207A-A (e.g., examples of output routing element 107 of FIG. 1). Similarly, waveguide resonators 201B-A through 201M-K can pass light to a respective drop routing element 207B-A through 207M-K. To block light, driver 206A can drive tuning component 214 coupled to waveguide resonator 201A-A to shift the resonance frequency and block (e.g., absorb) light at λ₁ on input routing element 204A. Driver(s) 206, in some examples, can drive the tuning component 214 by tuning a voltage bias applied to the tuning component that induces the shift. The waveguide resonators 201B-A through 201M-K can be similar driven to block light at corresponding wavelengths.

Returning to FIG. 2A, in performing an operation on the search words 203 encoded in accordance with Table 1, the driver(s) 206 can be configured to encode the QCAM stored words 213A-213M into the search engine 212 by tuning the plurality of modulators 201 in time to either allow light of the respective wavelength of the encoded search word to pass or to block the light, according to the encoding scheme of Table 2. For example, bits of each QCAM stored word 213A-213M can be encoded into a column of the M×K array of modulators 201 in time (e.g., different time slots) so to compare each bit of the search words 203 with each bit of the QCAM stored word 213A-213M. In the example of FIG. 2A, the driver(s) 206 can be configured to tune a first column 216 of modulators 201 with a first bit of the QCAM stored data word 213A during a first time slot t₁ and a second bit of the QCAM stored data word 213A during a second time slot t₂. Thus, referring to Table 2, to represent an encoded stored data bit value logic ‘1’, the modulators 201 in column 216 can be tuned to block light of an encoded wavelength during a first time slot t₁ and tuned to pass light at the encoded wavelength during the second time slot t₂. Each stored data word 213B-213M can be similarly encoded into a corresponding column of the search engine. In this example, two modulators 201 may constitute an O-QCAM cell, because two modulators 201 may be needed to represent a symbol value as two bit positions.

To provide for comparing a bit of each search word 203A-203K to a bit of each stored word 213A-213M, each modulator 201 of a given column of the M×K array is encoded according to a different wavelength (e.g., λ₁ through λₖ). The different wavelengths correspond to the different wavelengths used for carrying the bits of the search words 203A-203K, such that M and K are equal in this example. Such that a given column of the M×K array comprises a modulator 201 tuned to pass or block light for each wavelength carried on the encoded search signals 210A-210K. Accordingly, as an example referring to Table 2, to represent an encoded stored data bit value logic ‘1’, a first modulator 201 in column 216 can be tuned to block light of a first encoded wavelength during a first time slot t₁ and tuned to pass light at the first encoded wavelength during the second time slot t₂, while the kth modulator 201 in column 216 can be tuned to block light of a kth encoded wavelength during a first time slot t₁ and tuned to pass light at the kth encoded wavelength during the second time slot t₂. Similarly, to represent a logic ‘0’, the first modulator 201 in column 216 can be tuned to pass light of the first encoded wavelength during the first time slot t₁ and tuned to block light at the first encoded wavelength during the second time slot t₂, while the kth modulator 201 in column 216 can be tuned to pass light of a kth encoded wavelength during a first time slot t₁ and tuned to block light at the kth encoded wavelength during the second time slot t₂. To represent a wildcard value ‘X’, the first modulator 201 can be tuned to block light at the first encoded wavelength during time slots t₁, t₂ associated with the bit position, while the kth modulator 201 can be tuned to block light at the kth encoded wavelength during time slots t₁, t₂ associated with the bit position. To represent a reject value ‘ρ’, the first modulator 201 can be tuned to pass light at the first encoded wavelength during time slots t₁, t₂ associated with the bit position, while the kth modulator 201 can be tuned to pass light at the kth encoded wavelength during time slots t₁, t₂ associated with the bit position.

Based on the logic states indicated in Tables 1 and 2, according to an example, light will pass through the modulators 201 during a given time slot only when a mismatch occurs between the value of the bit position of the search words 203A-213N and the corresponding value of the bit position of the QCAM stored words 213A-213M. Table 3 shows the results based on the encoded bit value on the optical search signal and of the corresponding modulator 201. Light passed by the modulators 201 can be coupled (e.g., evanescently coupled in the case of a ring modulator, or other optical element capable of coupling light from a modulator) to a group of output routing elements 215A-215K, each of which represents a group of drop routing elements 207A-A through 207M-K (e.g., FIG. 2B) associated with a respective column. Each group of output routing element 215A-215K may be coupled to a subset of the modulators 201, for example, each group of output routing element 215A-215K may be coupled to a subset of modulators encoded according to a given stored word 213A-213M. For example, group of output routing element 215A, which may comprise drop routing elements 207A-A through 207K-A, is coupled to each of modulators 201 of column 216 encoded with bits for stored data word 213A. Thus, any mismatches occurring along the column 216 (e.g., light passed by modulators 201) can be coupled into the group of output routing elements 215A. Similarly, groups of output routing elements 215B-215K may receive light from respective modulators 201 representing mismatches of a respective comparison.

Photodetectors (e.g., implementations of photodetector 109 of FIG. 1) can be optically coupled to a result end of the groups of output routing elements 215A-215K in various examples. For example, as shown in FIG. 2B, photodetectors 209A-A through 209M-K can be optically coupled to a respective drop routing elements 207A-A through 207A-K and configured to sense the amplitude of light present on the respective drop routing element 207A-A through 207A-K, thereby detecting the mismatch and/or match for the respective bit position. Accordingly, each photodetector 209A-A through 209M-K may detect an amplitude of light at a corresponding wavelength of light, thereby detecting the mismatch and/or match for a respective bit position. In some examples, each photodetectors 209A-A through 209M-K can output a match/mismatch indication to an encoder circuit (not shown) configured to generate match addresses 1 through K corresponding to the stored words 213A-213M of the search engine 212 for which a match indication is received from photodetectors 209A-A through 209M-K. In some examples, each photodetector may send the indication to a processing circuit within the optical search engine 200 being configured to identify the memory address associated with the specific QCAM stored words represented by the search engine 212 and output an electrical signal to a memory controller or other device controller access to the memory storage.

In various examples, each photodetector 209A-A through 209M-K can be configured to integrate the mismatches over time for the duration of the search words 213A-213M (i.e., for the duration of the 2n time slots t, also referred to as a search cycle), enabling the each photodetector 209A-A through 209M-K to determine a sum of all mismatches between a given search word 213A-213M and a given QCAM stored word represented by the a column of the search engine 212. In some examples, the photodetectors 209A-A through 209M-K can be configured to flag or otherwise identify at which bit positions a mismatch occurred.

Note that since matches/mismatches are detected from drop routing elements 207A-A through 207A-K, in this example, the plurality of modulators may be tuned through operation of driver(s) 206 to represent an inverse of the bit value at bit positions of the QCAM stored words 213A-213M. This is because the coupling into respective drop routing elements 207A-A through 207A-K outputs an inverse of the state represented by the modulator and the input light. Thus, by tuning the modulators to represent inverse bits of the QCAM stored words 213A-213M, as shown in FIG. 2B, examples herein can output detect matches and mismatches in accordance with Table 3 above.

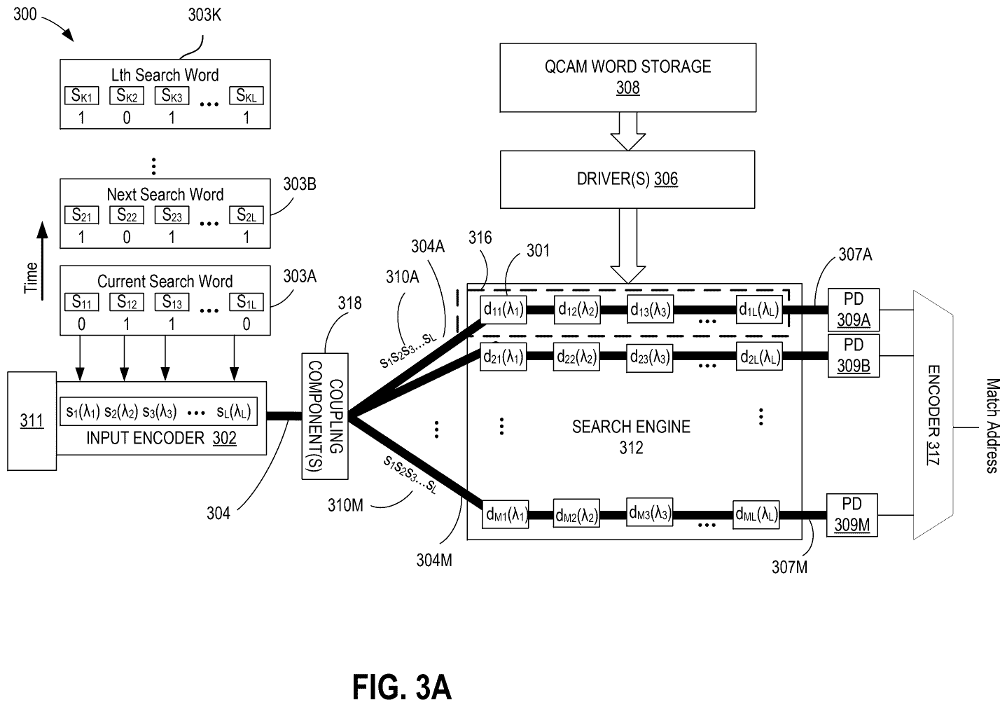

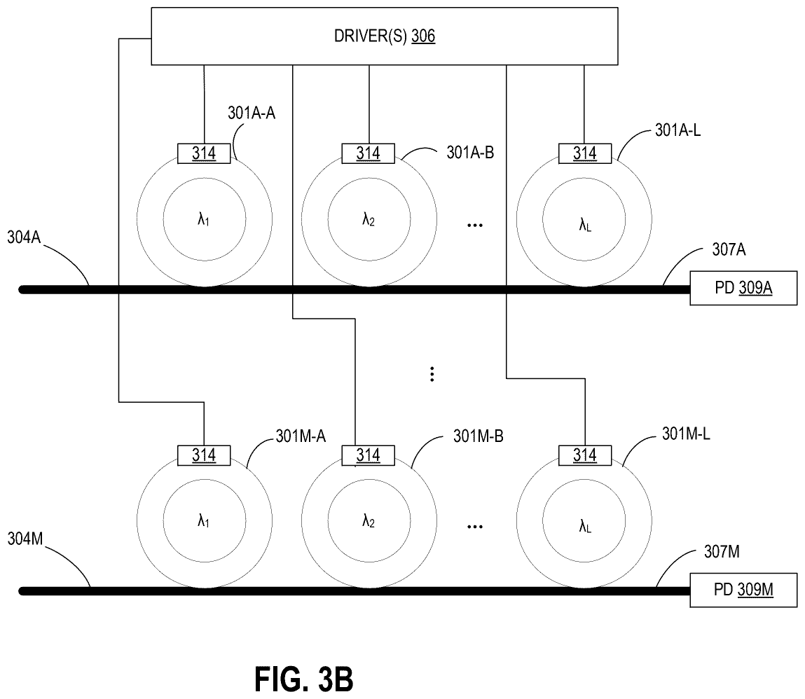

FIG. 3A illustrates an example optical search engine 300 in accordance another example of the present disclosure. The optical search engine 300, in this example, may be implemented to perform WDM O-QCAM in accordance with the examples herein. The optical search engine 300 is provided for illustrative purposes only and should not be interpreted as limiting the scope of the disclosed technology to only the depicted example. In examples, optical search engine 300 may be implemented to compare a number of K search words, each having a number of L bits, and a number M QCAM stored words, each having a number of L bits. In various examples, optical search engine 300 performs the comparison by optically executing matrix multiplication, for example, multiplying an L×K matrix representing the search words with an M×L matrix representing the QCAM stored words.

As shown in FIG. 3A, a plurality of search words 303A-303K (collectively referred to herein as search words 303) can be received an input encoder 302. The input encoder 302 may be substantially similar to input encoder 102 described above in connection with FIG. 1. For example, search words 303A-303K can be encoded by the input encoder 302 by modulating input optical signals provided by one or more optical source(s) 311 to generate encoded search signals 310A through 310M, similar to the encoding discussed with respect to FIGS. 1 and 2A. In various examples, the optical source(s) 311 can comprise one or more types of light emitting diodes (LEDs; potentially with subsequent narrow-band filters), multi-wavelength lasers (e.g., comb lasers), vertical cavity surface emitting lasers (VCSELs), or other light emission sources. In various examples, the optical source(s) 311 can be communicatively coupled to the input encoder 302 so that the input encoder 302 can encode the search words 303 on an optical signal of multiple wavelengths of light emitted by the optical source(s) 311. In some examples, input encoder 302 may be implemented using modulators to encode input light from optical source(s) 311 with the bits of the search words 303.

The input encoder 302 may be configured to encode the search words 303 in the wavelength domain. In various examples, each bit of a given search word 303 may be encoded using a different encoding wavelength according to encoding scheme described in Table 1 discussed above in connection with FIG. 1, while each search word 303 may be encoded during different time slots. For example, as shown in FIG. 3A, a first bit of search word 303A (e.g., logic “0”) can be encoded on first wavelength λ₁, a second bit of search word 303A (e.g., logic “1”) can be encoded on second wavelength λ₂, and so on until a Lth bit of search word 303A (e.g., logic “0”) can be encoded on a Lth wavelength λ_{L}. In this example, each search word 303 can be encoded during a different time slot t.

The encoded search signals 310A-310M generated by the input encoder 302 can be coupled to input routing elements 304A-304M via a coupling component 318. Each input routing elements 304A-304M may an example implementation of input routing element 104 of FIG. 1. The input routing elements 304A-304M can include one or more coupling components 318 disposed at the first end to couple the encoded search signals 310A-310M from the input encoder 302 and at the second end to couple the encoded search signals 310A-310M into a search engine 312. In the example of FIG. 3A, the input routing elements 304A-304M are coupled to a 1×M optical splitter, which splits an encoded search signal generated by the input encoder 302 into encoded search signals 310A-310M on the input routing elements 304A-304M into routing elements of the search engine 312.

In some examples, optical source(s) 311 may comprise multiple sources (e.g., a number G of optical sources) that supply multiple input optical signals to the input encoder 302. In this case, the input encoder 302 may generate a number G of encoded search signals. The NG encoded search signals may be input into G input routing elements each of which may include a coupling component. The coupling components, in this example, may be 1×M/G splitters, each of which may split a respective encoded search signal into encoded search signal 310A-310M that are coupled to the search engine 312 via input routing elements 304A-304M. This example may be useful where power budget restricts the amount of power that can be supplied to a single optical source 311.

To perform a WDM based search operation, the search engine 312 can be wavelength modulated to represent a plurality of QCAM stored words stored in QCAM word storage 308 (e.g., an example implementation of QCAM word storage 108 of FIG. 1). In various examples, the search engine 312 comprises a plurality of modulators 301, each of which may be implemented as modulator 101 of FIG. 1. In an illustrative example, each modulator 301 may be a waveguide resonator (e.g., ring modulator, ring filter, or the like) or other modulator component capable of being driven by an electronic signal to tune the performance characteristics of the modulators 301. In the example of FIG. 3A, the search engine 312 comprises an M×L array of modulators 301. For ease of illustration, only one modulator 301 is labeled with a reference number as an illustrative example.

The plurality of modulators may be tuned through operation of one or more driver(s) 306 (e.g., programming controller 106 of FIG. 1) to represent bit positions of the QCAM stored words stored in QCAM word storage 308. Each modulator 301 can be communicatively coupled to one or more tuning components, each of the one or more tuning components may be capable of changing an optical characteristic of the one or more modulators that make up each modulator 301 to enable tuning of the performance of the modulator 301. In various examples, the one or more tuning components can comprise one or more devices configured to change the refractive index of the core or cladding of the one or more modulators, control the number of free carriers, and/or create a red and/or blue shift of the resonance wavelength of the one or more modulators. Non-limiting examples of tuning components include heaters, electrical contacts, among other devices used to tune the resonance wavelength of optical components.

FIG. 3B illustrates an example implementation of search engine 312 in which the modulators are implemented as waveguide resonators 301A-A through 301M-L. In the example of FIG. 3B, search engine 312 comprises waveguide resonators 301A-A through 301M-L coupled to input routing element 304A-304M, as described in connection with FIG. 3B. The waveguide resonators 301A-A through 301M-L are arranged in rows. For example, as shown in FIG. 3B, waveguide resonators 301A-A through 301A-L are coupled to input routing element 304A and waveguide resonators 301M-A through 301M-L are coupled to input routing element 304M. The waveguide resonators 301A-A through 301M-L are designed for a plurality of resonance frequencies (e.g., λ₁ through λ_{L}), such that each row comprises one waveguide resonator of each resonance frequency.

The plurality of waveguide resonators 301A-A through 301M-L may be tuned through operation of driver(s) 306 to represent bit positions of the QCAM stored words. For example, each row of waveguide resonators 301A-A through 301M-L may be tuned according to a respective QCAM stored word. Each waveguide resonator 301A-A through 301M-L can be communicatively coupled to one or more tuning components 314 capable of changing an optical characteristic of the waveguide resonator 301A-A through 301M-L. In various examples, the one or more tuning components 314 can comprise one or more devices configured to change the refractive index of the waveguide resonators 301A-A through 301M-L that causes a shift of the resonance frequency. A shift in the resonance frequency can result in blocking an input optical signal that propagates at the un-shifted resonance frequency. For example, waveguide resonator 301A-A can have a resonance frequency corresponding to λ₁, which can pass light at λ₁ from the input routing element 304A to photodetector 309A (e.g., an example of photodetector 109 of FIG. 1). Similarly, waveguide resonators 301A-B through 301M-L can pass light to a respective photodetector 309A-309M. To block light, driver 306 can drive tuning component 314 coupled to waveguide resonator 301A-A to shift the resonance frequency and block (e.g., absorb) light at λ₁ on input routing element 304A. Driver(s) 306, in some examples, can drive the tuning components 314 by tuning a voltage bias applied to the tuning components that induces the shift. The waveguide resonators 301A-B through 301M-L can be similar driven to block light a corresponding wavelengths.

Returning to FIG. 3A, in performing an operation on the search words 303 encoded in accordance with Table 1, the driver(s) 306 can be configured to encode the QCAM stored words into the search engine 312 by tuning the plurality of modulators 301 to either allow light of an encoded wavelength to pass or to block the light of the encoded wavelength, according to the encoding scheme of Table 2. For example, each QCAM stored word can be encoded into a respective row of the M×L array of modulators 301. For example, row 316, as an illustrative example, can be encoded with a first QCAM stored word, while each other row can be encoded with a respective QCAM stored word. The driver(s) 306 can be configured to encode each modulator 301 of a given row with a bit value of the respective QCAM stored word. Each QCAM stored word may be associated with multiple wavelengths, and the driver(s) 306 may be configured to tune the modulators 301 of a respective row to allow light of the wavelengths to pass or to block light of the wavelengths according to the encoding scheme of Table 2. As an illustrative example, the driver(s) 306 can be configured to tune a first modulator of row 316 to block or pass light of a first wavelength according to a first bit of a first QCAM stored data word (e.g., logic “0” in this example), tune a second modulator of row 316 to block or pass light of the second wavelength according to a second bit of the first QCAM stored data word (e.g., logic “1” in this example), and so on down to a Lth modulator of row 316 can be tuned to pass or block light of the Lth wavelength according to an Lth bit of the first QCAM stored data word (e.g., logic “0” in this example). Each QCAM stored data word is similarly encoded to a particular row, until the Mth row is encoded. In this example, two modulators 301 may constitute an O-QCAM cell, because two modulators 301 may be needed to represent a symbol value as two bit positions.

Based on the logic states indicated in Tables 1 and 2, light will pass through the modulators 301 only when a mismatch occurs between the value of the bit position of a given search word 303 and the corresponding value of the bit position of the QCAM stored words. Table 3 shows the results based on the encoded bit value on the optical search signal and of the corresponding modulator 301. Light passed by the modulators 301 can be coupled to output routing elements 307A-307M (e.g., examples of output routing element 107 of FIG. 1). Each output routing element 307A-307M may be coupled to a subset of the modulators 301, for example, each output routing element 307A-307M may be coupled to a row of the M×L array of modulators. For example, output routing element 307A is coupled to each of modulators of a row 316 encoded with bits for the first QCAM stored data word. Thus, any mismatches occurring along the row 316 (e.g., light passed by modulators 301) can be coupled into output routing element 307A, representing mismatches of the current search word 303 with bits of the stored data word. Similarly, output routing element 307B-307M may receive light from respective modulators 301 representing mismatches of a comparison on a respective row.

Photodetectors 309A-309M (e.g., implementations of photodetector 109 of FIG. 1) can be optically coupled to a result end of the output routing element 307A-307M in various examples. The photodetectors 309A-309M can be configured to sense the amplitude of light present on the respective output routing element 307A-307M, thereby detecting the mismatch and/or match for the respective bit position. In some examples, demultiplexers may be disposed between the search engine 312 and photodetectors 309A-309M, configured to filter various wavelengths of light on to respective downstream routing elements coupled to photodetectors. In this case, each photodetectors 309A-309M may comprise a set of photodetectors for detecting amplitudes of light at each wavelength of light, thereby detecting the mismatch and/or match for a respective bit position. In some examples, each photodetectors 309A-309M can output a match/mismatch indication to an encoder circuit 317 configured to generate the memory address corresponding to the QCAM stored data words of the search engine 312 for which a match indication is received from photodetectors 309A-309M. In some examples, each photodetector may send the indication to a processing circuit within the optical search engine 300 being configured to identify the memory address associated with the specific QCAM stored words represented by the search engine 312 and output an electrical signal to a memory controller or other device controller access to the memory storage.

In various examples, each photodetector 309A-309M can be configured with a wide bandwidth, enabling each photodetector 309A-309M to detect match states resulting from a comparison between search word 303 and each QCAM stored word. In some examples, the photodetectors 309A-309M can be configured to flag or otherwise identify at which bit positions a mismatch occurred.

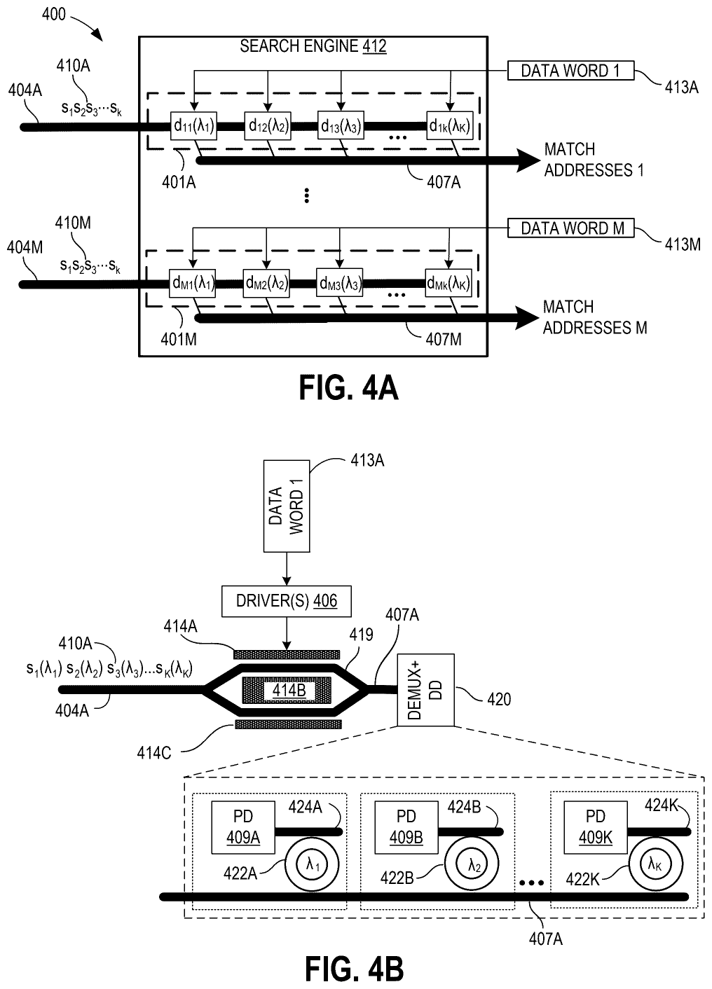

FIG. 4A illustrates an example optical search engine 400 in accordance yet another example of the present disclosure. The optical search engine 400, in this example, may be implemented to perform TDM O-QCAM in accordance with the examples herein. The optical search engine 400 is provided for illustrative purposes only and should not be interpreted as limiting the scope of the disclosed technology to only the depicted example. Similar to optical search engine 200 of FIG. 2A, optical search engine 400 may be implemented to compare a number of K search words, each having a number of L bits, and a number M QCAM stored words, each having a number of L bits.

Optical search engine 400 can be configured to generate encoded search signals 410A-410M by an input encoder in a manner described above in connection with FIG. 2A. As such, encoded search signals 410A-410M may be substantially similar to encoded search signals 210A-210K, except of a number of M encoded search signals are provided (e.g., the number of QCAM stored words). Furthermore, encoded search signals 410A-410M can be coupled to input routing elements 404A-404M, which may be examples of input routing elements 204A-204M. Accordingly, the description above in connection with FIG. 2A applies equally to optical search engine 400, which may comprise optical sources (e.g., optical source(s) 211), coupling components (e.g., coupling components 218), and other elements described above in connection with FIG. 2A. Thus, input routing elements 404A-404M can include one or more coupling components to couple the encoded search signals 410A-410M from an input encoder into a search engine 412.

To perform a TDM based search operation, the search engine 412 can be wavelength modulated to represent a plurality of QCAM stored word 413A-413M. In various examples, the search engine 412 comprises a plurality of modulators 401A-401M, each of which may be implemented as modulator 101 of FIG. 1. In an illustrative example, each modulator 401A-401M may be a Mach Zehnder Modulator (MZM) or other modulator component capable of being driven by an electronic signal to tune the performance characteristics of the modulators 401A-401M. In the example of FIG. 4A, the search engine 412 comprises an M×1 array of modulators 401A-401M, each associated with a QCAM stored data word.

The plurality of modulators may be tuned through operation of one or more driver(s) (e.g., driver(s) 206 of FIG. 2A) to represent bit positions of the QCAM stored words 413A-413M. Each modulator 401A-401M can be communicatively coupled to one or more tuning components capable of changing an optical characteristic of the one or more modulators. In various examples, the one or more tuning components can comprise one or more devices configured to change the refractive index of the core or cladding of the one or more modulators, control the number of free carriers, and/or create a red and/or blue shift of the resonance wavelength of the one or more modulators. Non-limiting examples of tuning components include heaters, electrical contacts, among other devices used to tune a phase of optical components. As an example, each modulator 401A-401M can be tuned, via operation of the driver(s) 406 (shown in FIG. 4B) to represent bits of each QCAM stored word 413A-413M. That is, for example, modulator 401A can be tuned to represent bits d₁ through d_{L} of QCAM stored word 413A, while modulator 401M can be tuned to represent bits d₁ through d_{L} of QCAM stored word 413M. Thus, each modulator 401A-401M can be tuned to represent an entire respective QCAM stored word 413A-413M. As described below, QCAM stored word 413A-413M can then compared against bits of each search word (e.g., 203A-203K), encoded into encoded search signals 410A-410M, during different time slots. For example, first bits of each search word (e.g., search words 303A-303K), encoded into encoded search signals 410A-410M, can be compared to the entirety of each QCAM stored word 413A-413M during a first time slot via modulators 401A-401M; second bits of each search word can be compared to the entirety of each QCAM stored word 413A-413M during a second time slot; and so on until the Lth bit of each search word can be compared to the entirety of each QCAM stored word 413A-413M during an Lth time slot.

FIG. 4B illustrates an example implementation of modulator 401A, as an example of modulator 401A-401M, in which the modulators are implemented using an MZM 419. In the example of FIG. 4B, MZM 419 can be coupled to input routing element 404A. The MZM 419, in this example, can be implemented as a broadband modulator that configured to modulate the phase of multiple wavelengths (e.g., λ₁ through λ_{K}) independent of other wavelengths, such that each constructive and/or destructive interference occurs at the output of the MZM 419 on a per wavelength basis.

The MZM 419 may be tuned through operation of driver(s) 406 (e.g., driver(s) 306 of FIG. 3A) to represent bit positions of the QCAM stored words. For example, MZM 419 may be tuned according to a respective QCAM stored word. MZM 419 can be communicatively coupled to one or more tuning components 414A-414C capable of changing an optical characteristic of each arm of MZM 419. Based on differences in the optical characteristics, for each wavelength, between the arms of the MZM 419, destructive or constructive interference occurs that either blocks or passes light to output routing element 407A (e.g., an example implementation of output routing element 107 of FIG. 1). In various examples, the one or more tuning components can comprise one or more devices configured to change the refractive index of the waveguide constituting each arm of MZM 419 that causes a shift in the phase, on a per wavelength basis, of light propagating thereon, which can result in destructive or constructive interference. For example, constructive interference can occur at the output of MZM 419 for light of wavelength λ₁, which can pass this light to detector component 420. Similarly, MZM 419 can pass light at wavelengths λ₂ through λ_{K}. To block light, driver 406 can drive tuning components 414A-414C coupled to MZM 419 to shift the phase and block (e.g., destructive interference) light at λ₁. Driver(s) 406, in some examples, can drive the tuning components 414A-414C by tuning voltage biases applied to the tuning components 414A-414C that induces the shift. The MZM 419 can be similar driven to block light a wavelengths λ₂ through λ_{K}.

Returning to FIG. 4A, in performing an operation on the search words encoded in accordance with Table 1, the driver(s) can be configured to encode the QCAM stored words 413A-413M into the search engine 412 by tuning the plurality of modulators 401A-401M to either allow light of an encoded wavelength to pass or to block the light of the encoded wavelength, according to the encoding scheme of Table 2. For example, each QCAM stored word 413A-413M can be encoded into a respective row of search engine 412. For example, modulator 401A can be encoded with a first QCAM stored word, while each other row can be encoded with a respective QCAM stored word. The driver(s) can be configured to retrieve the QCAM stored word 413A-413M from memory (e.g., QCAM word storage 108 of FIG. 1) encode each modulator 401A-401M with a bit value of the respective QCAM stored word. Each QCAM stored word may be associated with multiple wavelengths, and the driver(s) may be configured to tune the modulators 401A-401M to allow light of the wavelengths to pass or to block light of the wavelengths according to the encoding scheme of Table 2. As an illustrative example, the driver(s) can be configured to tune a modulator 401A (e.g., as shown in FIG. 4B) to block or pass light of a first wavelength according to a first bit of a first QCAM stored data word, tune a modulator 401A to block or pass light of the second wavelength according to a second bit of the first QCAM stored data word, and so on until the modulator 401A can be tuned to pass or block light of the Lth wavelength according to an Lth bit of the first QCAM stored data word. Each QCAM stored data word can be similarly encoded to a modulator 401B-401M. In this example, each modulator 401B-401M may constitute a distinct O-QCAM cell, because each modulator 401B-401M can be implemented to represent one or more symbol values.

Based on the logic states indicated in Tables 1 and 2, light will pass through the modulators 401A-401M only when a mismatch occurs between the value of the bit position of a given search word and the corresponding value of the bit position of the QCAM stored words 413A-413M. Table 3 shows the results based on the encoded bit value on the optical search signal and of the corresponding modulator 401A-401M. Light passed by the modulators 401A-401M can be coupled to output routing elements 407A-407M (e.g., examples of output routing element 107 of FIG. 1). Each output routing element 407A-407M may be coupled to a modulator 401A-401M, respectively. Thus, any mismatches occurring along the modulator 401A can be coupled into output routing element 407A, representing mismatches of the current search word with bits of the stored data word 413A. Similarly, output routing element 407B-407M may receive light from respective modulators 401B-401M representing mismatches of a comparison on a respective row.

Detector components, an example of which is shown in FIG. 4B as detector component 420, can be optically coupled to a result end of the output routing element 407A-407M in various examples. Each detector component may include a set of photodetectors, illustratively shown in FIG. 4B as photodetectors 409A-409K, that can be configured to sense an amplitude of light, at a respective wavelength, present on a respective output routing element, thereby detecting the mismatch and/or match for the respective bit position. That is, referring to FIG. 4B as an example, photodetectors 409A-409K can be configured to sense an amplitude of light, at a respective wavelength λ₁ through λ_{K}, present on output routing element 407A, thereby detecting the mismatch and/or match for the respective bit position.

In some examples, each detector component comprises demultiplexers disposed between the search engine 412 and respective set of photodetectors, configured to filter the various wavelengths of light on to respective downstream routing elements coupled to the photodetectors. For example, in the illustrative example of FIG. 4B, detector component 420 comprises demultiplexers 422A-422K optically coupled between output routing element 407A and downstream routing elements 424A-424K, respectively. Each demultiplexer 422A-422K, which is illustratively implemented as a waveguide resonator, is configured to filter a respective wavelength of light propagating on the output routing element 407A and couple the light into downstream routing elements 424A-424K. The coupled light can then be supplied to a respective photodetector 409A-409K. In the case of waveguide resonators, the demultiplexers 422A-422K may have resonance frequencies corresponding to one of the encoded wavelengths (e.g., wavelengths λ₁ through λ_{K}), which enables the filtering described above. The set of photodetectors 409A-409K for detecting amplitudes of light at a respective wavelength of light coupled from a respective demultiplexer 422A-422K, thereby detecting the mismatch and/or match for a respective bit position.

In some examples, each detector component can output a match/mismatch indication to an encoder circuit (e.g., encoder circuit 317 of FIG. 3A) configured to generate the memory address corresponding to the QCAM stored data words of the search engine 412 for which a match indication is received from detector components. In some examples, each detector component may send the indication to a processing circuit communicably connected to the optical search engine 400 being configured to identify the memory address associated with the specific QCAM stored words represented by the search engine 412 and output an electrical signal to a memory controller or other device controller access to the memory storage.

In various examples, each detector component can be configured to integrate the mismatches over time for the duration of the search words (i.e., for the duration of the 2n time slots t, also referred to as a search cycle), enabling each detector component to determine a sum of all mismatches between a given search word and a given QCAM stored word 413A-413M. In some examples, the detector components can be configured to flag or otherwise identify at which bit positions a mismatch occurred.

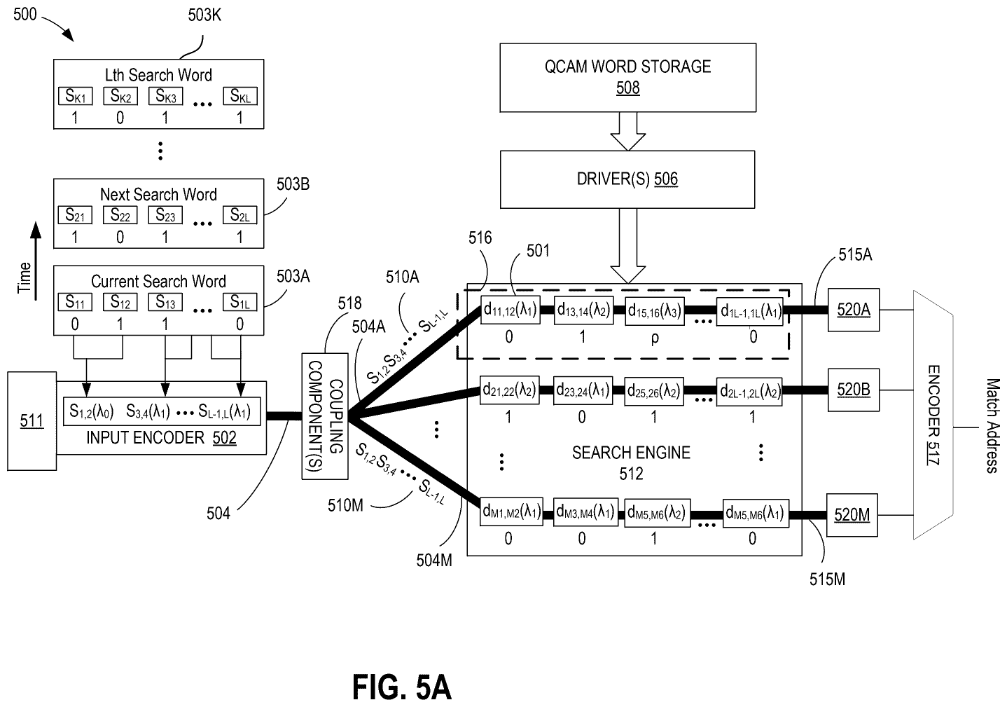

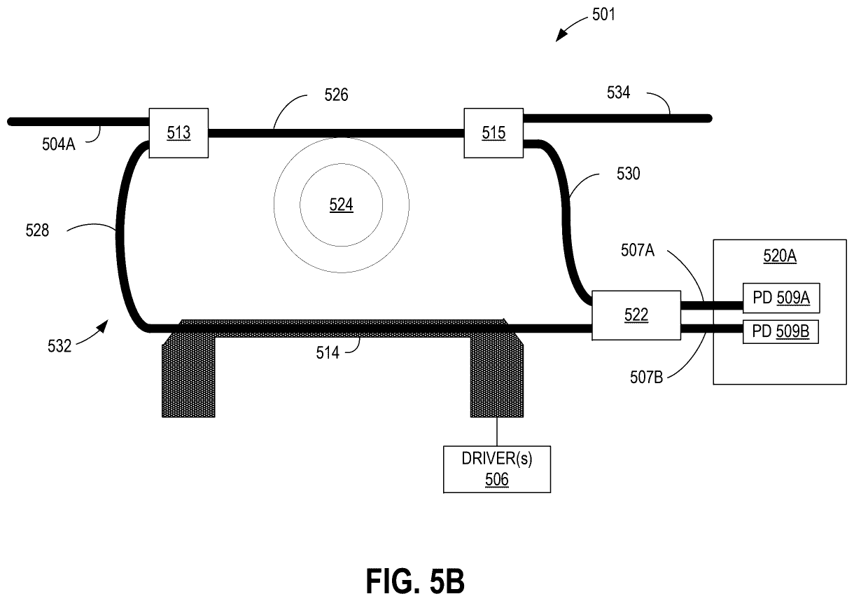

FIG. 5A illustrates an example optical search engine 500 in accordance another example of the present disclosure. The optical search engine 500, in this example, may be implemented to perform WDM O-QCAM in accordance with the examples herein, similar to optical search engines 300 of FIG. 3A. The optical search engine 500 is provided for illustrative purposes only and should not be interpreted as limiting the scope of the disclosed technology to only the depicted example. Optical search engine 500 may be implemented to compare a number of K search words, each having a number of L bits, and a number M QCAM stored words, each having a number of L bits.

As shown in FIG. 5A, a plurality of search words 503A-503K (collectively referred to herein as search words 503) can be received an input encoder 502. The input encoder 502 may be substantially similar to input encoder 102 described above in connection with FIG. 1. For example, search words 503A-503K can be encoded by the input encoder 502 by modulating input optical signals provided by one or more optical source(s) 511 to generate encoded search signals 510A through 510M, similar to the encoding discussed with respect to FIGS. 1, 3A, and 3B. The optical source(s) 511 may be substantially similar to the optical source(s) 311 of FIG. 3A. In various examples, the optical source(s) 511 can be communicatively coupled to the input encoder 502 so that the input encoder 502 can encode the search words 503 on an optical signal of multiple wavelengths of light emitted by the optical source(s) 511. In some examples, input encoder 502 may be implemented using modulators to encode input light from optical source(s) 511 with the bits of the search words 503.

The input encoder 502 may be configured to encode the search words 503 in the wavelength domain. Unlike prior examples, input encoder 502 may be configured to encode each search word according to an encoding scheme provided in Table 4 below.

TABLE 4

| | Encoded | Encoded | |
|---|---|---|---|
| Search | Search | Search | |
| Word | Signal Bit | Signal Bit | Input |
| Symbol | Value (s₁) | Value (s₂) | Wavelength |
| 0 | 0 | 1 | λ₀ |
| 1 | 1 | 0 | λ₁ |
| X | 0 | 0 | 0 |
| ρ | 1 | 1 | λ₀, λ₁ |

As shown in Table 4, each search word symbol can be represented by two encoded search bit values s₁, s₂. To provide a search word symbol of logic ‘0’, light having a wavelength λ₀ can be transmitted within the first encoded search bit value s₁ associated with the bit position and within the second encoded search bit value s₂. For the search word symbol of logic ‘1’, light having a wavelength λ₁ can be transmitted within the first encoded search bit value s₁ associated with the bit position and within the second encoded search bit value s₂. To provide a search of wildcard symbol ‘X’, light amplitude of 0 (e.g., no light) can be transmitted in both of the first encoded search bit value s₁ and the second encoded search bit value s₂. To provide the search word symbol ‘ρ’, light of any wavelength (e.g., λ₀ and/or λ₁) can be transmitted in both of the first encoded search bit value s₁ and the second encoded search bit value s₂. In this example, each search word 503 can be encoded during a different time slot t.

The encoded search signals 510A-510M generated by the input encoder 502 can be coupled to input routing elements 504A-504M via a coupling component 518. Each input routing elements 504A-504M may be an example implementation of input routing element 104 of FIG. 1. The input routing elements 504A-504M can include one or more coupling components 518 disposed at the first end to couple the encoded search signals 510A-510M from the input encoder 502 and at the second end to couple the encoded search signals 510A-510M into a search engine 512. In the example of FIG. 5A, the input routing elements 504A-504M can be coupled to a 1×M optical splitter, which splits an encoded search signal generated by the input encoder 502 into encoded search signals 510A-510M on the input routing elements 504A-504M into routing elements of the search engine 512. In some examples, as described above in connection with FIG. 3A, a number of G optical sources 511 may be used and the coupling components may be 1×M/G splitters, each of which may split a respective encoded search signal into encoded search signal 510A-510M that are coupled to the search engine 512 via input routing elements 504A-504M.

To perform a search operation, the search engine 512 can be wavelength modulated to represent a plurality of QCAM stored words stored in QCAM word storage 508 (e.g., an example implementation of QCAM word storage 108 of FIG. 1). In various examples, the search engine 512 comprises a plurality of modulators 501, each of which may be implemented as modulator 101 of FIG. 1. In an illustrative example, each modulator 501 may comprise a waveguide resonator (e.g., ring modulator) or other modulator components capable of being driven by an electronic signal to tune the performance characteristics of the modulators 501. In the example of FIG. 5A, the search engine 512 comprises an M×L/2 array of modulators 501 (e.g., one modulator for each QCAM search word symbol). For ease of illustration, only one modulator 501 is labeled with a reference number as an illustrative example.

The plurality of modulators may be tuned through operation of one or more driver(s) 506 (e.g., programming controller 106 of FIG. 1) to represent bit positions of the QCAM stored words stored in QCAM word storage 508. Each modulator 501 can be communicatively coupled to one or more tuning components, each of the one or more tuning components may be capable of changing an optical characteristic of the one or more modulators that make up each modulator 501 to enable tuning of the performance of the modulator 501. In various examples, the one or more tuning components can comprise one or more devices configured to change the refractive index of the core or cladding of the one or more modulators, control the number of free carriers, and/or create a red and/or blue shift of the resonance wavelength of the one or more modulators. Non-limiting examples of tuning components include heaters, electrical contacts, among other devices used to tune the resonance wavelength of optical components.

FIG. 5B illustrates an example implementation of a modulator 501 that can be included in search engine 512. In the example of FIG. 5B, modulator 501 is provided as an illustrative example, and each modulator of the search engine 512 may be implemented in a similar manner as described herein. Modulator 501 comprises a waveguide resonator 524 coupled to a branch waveguide 526 of an interferometer 532. In the example of FIG. 5B, branch waveguide 526 is coupled to input routing element 504A via a coupling component 513. Coupling component 513 may be implemented as a 2×1 multi-mode interference (MMI) coupler in this example. Light on input routing element 504A is first passed through coupling component 513 and couples into the waveguide resonator 524. Based on the resonance frequency of the waveguide resonator 524, clockwise (CW) propagating light (also referred to as transmitted light) may couple back to the branch waveguide 526. Coupling component 513 in this example, may be 1×2 MMI coupler acting as a 50/50 splitter. Counterclockwise (CCW) propagating light (also referred to as reflected light) may reflect back toward the coupling component 513 when the transmitted light couples back into the branch waveguide 526. The coupling component 513 acts as a splitter for the reflected light which is guided through a feedback waveguide 528 towards a coupling component 522 (e.g., a 2×2 MMI coupler in this example). The transmitted light is passed to the coupling component 515 and is split equally between a drop waveguide 534 and a coupling component 522 via waveguide 530, where the transmitted light is recombined with the reflected light. The coupling component 522 passes the recombined light to output routing elements 507A and 507B connected to a detector component 520A.

The recombined light from the coupling component 522 is the result of interference between the transmitted and reflected light and are detected by photodetectors 509A and 509B. Interference may be constructive or destructive depending on the phase difference between the transmitted and reflected light. To adjust this phase to obtain the desired interference, a tuning component 514B is coupled to the feedback waveguide 528, for example, a resistive heater element. By setting a current through the tuning component 514B, the phase difference can be tuned for constructive or destructive interference.

The modulator 501 may be tuned through operation of driver(s) 506 (e.g., programming controller 106 of FIG. 1) to represent symbols of the QCAM stored words. For example, modulator 501 may be tuned according to a respective QCAM stored word according to the encoding scheme shown in Table 4 below.

TABLE 5

| | Encode Stored | Encode Stored | |
|---|---|---|---|
| QCAM Stored | Data Bit | Data Bit | Resonance |
| Word Symbol | Value (d₁) | Value (d₂) | Wavelength |
| 1 | 0 | 1 | λ₀ |
| 0 | 1 | 0 | λ₁ |
| X | 0 | 0 | λ₀, λ₁ |
| ρ | 1 | 1 | Detuned/None |

Modulator 501 can be communicatively coupled to one or more tuning components 514 capable of changing an optical characteristic of interferometer 532. Based on differences in the optical characteristics within the modulator 501, light can be blocked or passed light to output routing elements 507A and 507B (e.g., an example implementations of output routing element 107 of FIG. 1). In various examples, the one or more tuning components 514 can comprise one or more devices configured to change the refractive index of a waveguide constituting each branch of interferometer 532 that causes a shift in the phase of light propagating thereon. For example, two resonance frequencies can be achieved due to back scattering in the interferometer 532. For example, Eigen modes can of an optical signal input into the interferometer 532 via input routing elements 504A be centered around Eigen frequencies ω=ω₀±½γ, where γ represents a scattering lifetime. As a result, optical signals traveling on the waveguide 530 can have one resonance frequency and optical signals traveling on the waveguide 528 can have another resonance frequency. Thus, examples herein can independently tune each resonance frequency via tuning components 514 by causing a shift in the phase of light propagating thereon to select a desired resonance frequency (e.g., none, λ₀, λ₁, or both) and, thereby, encoding a desired symbol according to Table 5 above.

Returning to FIG. 5A, in performing an operation on the search words encoded in accordance with Table 4, the driver(s) 506 can be configured to encode the QCAM stored words into the search engine 512 by tuning the modulators to either allow light of an encoded wavelength to pass or to block the light of the encoded wavelength, according to the encoding scheme of Table 5. For example, each QCAM stored word, stored in QCAM word storage 508, can be provided to driver(s) 506 and used to encode each QCAM stored word into a respective row search engine 512. For example, modulators of row 516 can be encoded with a first QCAM stored word, while each other row can be encoded with a respective QCAM stored word. The driver(s) 506 can be configured to encode each modulator of a given row with a symbol value of the respective QCAM stored word. Each QCAM stored word may be associated with multiple wavelengths, and the driver(s) 506 may be configured to tune the modulators to allow light of the encoded wavelengths to pass or to block light of the encoded wavelengths according to the encoding scheme of Table 5. As an illustrative example, the driver(s) 506 can be configured to tune modulator 501 (e.g., as shown in FIG. 5B) to block or pass light of an encoded wavelength according to a first symbol value of a first QCAM stored data word (e.g., λ₀ for the case of logic “0” in this example), tune a second modulator to block or pass light of an encoded wavelength according to a second symbol of the first QCAM stored data word (e.g., λ₁ for the case of logic “1” in this example), and so on until the final modulator can be tuned to pass or block light of an encoded wavelength according to an (L/2)th symbol of the first QCAM stored data word (e.g., λ₀ for the case of logic “0” in this example). In the case of a “ρ”, a modulator can be detuned to block light of any encoded wavelength. In the case of an “X”, a modulator can be detuned to pass light of any encoded wavelength. Each QCAM stored data word can be similarly encoded to a respective row of the search engine 512. In this example, each modulator 501 may constitute a distinct O-QCAM cell, because each modulator 501 may be implemented to represent a symbol value.

Based on the logic states indicated in Tables 4 and 5, light will pass through the modulators 501 only when a mismatch occurs between the value of the symbol of a given search word 503 and the corresponding value of the symbol of the QCAM stored words. Table 6 shows the results based on the encoded symbol value on the optical search signal and of the corresponding modulator 401.

TABLE 6

| Search Word | QCAM Stored | Match/ | |
|---|---|---|---|
| Symbol | Word Symbol | Mismatch State | Throughput |
| 0 | 0 | Match | 0 |
| 0 | 1 | Mismatch | λ₀ |
| 0 | X | Match | 0 |
| 0 | ρ | Mismatch | λ₀ |
| 1 | 0 | Mismatch | λ₁ |
| 1 | 1 | Match | 0 |
| 1 | X | Match | 0 |
| 1 | ρ | Mismatch | λ₁ |
| X | 0 | Match | 0 |
| X | 1 | Match | 0 |
| X | X | Match | 0 |
| X | ρ | Match | 0 |
| ρ | 0 | Mismatch | λ₁ |
| ρ | 1 | Mismatch | λ₀ |
| ρ | X | Match | 0 |
| ρ | ρ | Mismatch | λ₀, λ₁ |

Light passed by the modulators 501 can be coupled to groups of output routing elements 515A-515M, each of which represents a group of output routing elements 507A and 507B (e.g., FIG. 5B). Each group of output routing elements 515A-515M may be coupled to a subset of the modulators 501, for example, each group of output routing element 515A-515M may be coupled to a row of the search engine 512. For example, group of output routing elements 515A is coupled to each of modulators of a row 516 encoded with symbols for the first QCAM stored data word. Thus, any mismatches occurring along the row 516 (e.g., light passed by modulators 501) can be coupled into the group of output routing elements 515A, representing mismatches of the current search word 503 with symbols of the stored data word. Similarly, groups of output routing element 515B-515M may receive light from respective modulators representing mismatches of a comparison on a respective row.

Detector components 520A-520M, an example of which is shown in FIG. 5B as detector component 520A, can be optically coupled to a result end of the group of output routing element 515A-515M in various examples. Each detector component 520A-520M may be configured to detect throughput from Table 6. In this example, detector component 520A-520M may each include a set of photodetectors, illustratively shown in FIG. 5B as photodetectors 509A and 509B, that can be configured to sense light present on a respective output routing element. The photodetectors 509A and 509B can detect the presence (or absence) of light at a particular encoded wavelength, thereby detecting the mismatch and/or match for the respective symbol according to Table 6 above. That is, referring to FIG. 5B as an example, photodetectors 509A and 509B can be configured to sense an amplitude of light, at wavelength λ₁ and/or λ₀, present on output routing element 507A and/or 507B, thereby detecting the mismatch and/or match for the respective bit position. For example, photodetector 509A can be configured to sense an amplitude of light at wavelength λ₁ present on output routing element 507A and photodetector 509B can be configured to sense an amplitude of light at wavelength λ₀ present on output routing element 507B. While the above example describes utilizing both photodetectors 509A and 509B, examples herein may be utilize one of photodetectors 509A and 509B. That is, for example, determinations according to Table 6 may be made using either photodetector 509A or photodetector 509B to sense an amplitude of light at wavelengths λ₁ and λ₀.

In some examples, each detector component comprises demultiplexers (e.g., such as shown in FIG. 4B) disposed between the search engine 512 and respective set of photodetectors, configured to filter the various wavelengths of light on to respective downstream routing elements coupled to the photodetectors.

In some examples, each detector component can output a match/mismatch indication to an encoder circuit 517 configured to generate the memory address corresponding to the QCAM stored data words of the search engine 512 for which a match indication is received from detector components. In some examples, each detector component may send the indication to a processing circuit within the optical search engine 500 being configured to identify the memory address associated with the specific QCAM stored words represented by the search engine 512 and output an electrical signal to a memory controller or other device controller access to the memory storage.

In various examples, each detector component can be configured to integrate the mismatches over time for the duration of the search words (i.e., for the duration of the 2n time slots t, also referred to as a search cycle), enabling each detector component to determine a sum of all mismatches between a given search word and a given QCAM stored word. In some examples, the detector components can be configured to flag or otherwise identify at which bit positions a mismatch occurred.

The example of FIGS. 5A and 5B can provide for power savings and reduced energy consumption during a search. This is because, the examples described above in connection with FIGS. 5A and 5B are configured to represent a symbol using a single modulator and thus one tuning component. Whereas, other examples may rely on two modulators to represent a symbol, for example, by representing two bit positions that constitute a symbol, which requires additional tuning components and complexity.

While optical search engine 500 is described with reference to modulator 501 shown in FIG. 5B, examples herein need not be limited to this specific example. Other optical modulator or filters may be implemented that can be operated to control a resonance frequency so to achieve the encoding scheme set forth in Tables 5 and 6. For example, backcoupling manipulation in ring resonators, as known in the art, can be utilized to control resonance. These devices can be implemented as a modulator that can be tuned to represent QCAM stored words according to Table 5.

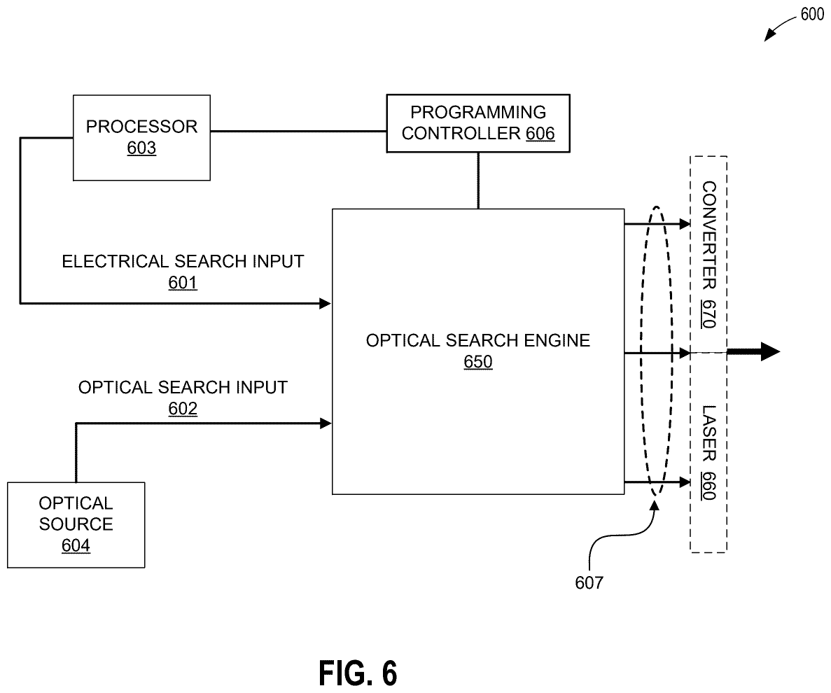

The optical search engines discussed with respect to FIGS. 1-5B can be implemented within a QCAM component of a device, increasing the speed and efficiency of the search compared to traditional bCAMs and TCAMs. FIG. 6 illustrates an example computing device 600 in accordance with examples of the technology disclosed herein. The example computing device 600 is provided for illustrative purpose and should not be interpreted as limiting the scope of the technology only to the depicted example. The example computing device 600 may include more or fewer components in various examples. When common references are used between figures, it should be interpreted that all descriptions associated with such reference is applicable to all instances of the reference unless otherwise stated.

As shown in FIG. 6, the computing device 600 can comprise a processor 603. In various examples, the processor 603 can be one or more of a general purpose processor (GPU), an application specific integrated circuit (ASIC), a field programmable gate array (FPGA), or other computer processor device known in the art. In various examples, the processor 603 can comprise a co-processor configured to control operation of the QCAM search functionality of the computing device 600. In some examples, the processor 603 can be configured to send an electrical search word to optical search engine 650. In various examples, the optical search engine 650 can be configured to implement the examples discussed above with respect to FIGS. 1-5B. One or more applications executed by the processor 603 may request access to a portion of memory within the same network as the computing device 600 by submitting a search word electronically of the electrical search input line 601. The optical search engine 650 can encode the search word on the optical search signals, as discussed with respect to FIGS. 1-5B. In various examples, the search word may be submitted to the optical search engine 650 optically over the optical search input 602 from an optical source 604.

In various examples, the optical source 604 may comprise an output from an optical transceiver (not shown in FIG. 6) of the computing device 600. The optical transceiver may be configured to receive an optical signal encoded with the search word from one or more other devices connected to the computing device 600. In some examples, the optical source 604 can comprise an optical fiber or other optical transmission medium within the computing device 600 and connected to one or more other components within the computing device and/or to the interior output of a faceplate connector. The optically-received search word over the optical search input 602 can be multiplexed into the plurality of optical search signals like that discussed with respect to FIGS. 1-5B.

In various examples, the processor 603 can be communicatively coupled to the programming controller 606. As discussed with respect to FIGS. 1-5B, the programming controller 606 can be configured to program the plurality of modulators within the optical search engine 650 such that the state of each modulator is driven in accordance with the encoding scheme discussed with respect to Tables 2 and 5. In various examples, the processor 603 may send a word to be stored to the programming controller 606, which can then determine how the electrical drive signal should be encoded. In some examples, the processor 603 and the programming controller 606 may be the same component. In some examples, the programming controller 606 can be configured to receive instructions for operation of the modulators of the optical search engine 650 for each word.

After performing the search, one or more output signals 607 may be output by the optical search engine 650. In various examples, the output signals 607 can comprise one or more memory addresses in a memory component within the network and accessible by the computing device 600, whether directly or indirectly (i.e., through another device within the network), corresponding to one or more stored words represented by the plurality of modulators of the optical search engine 650 that were determined to match the search word. The output signal 607 can be sent to either a converter 670, a laser 660, or a combination of both. If the memory address corresponding to the matched QCAM stored word(s) is to be sent to an electronic component (e.g., a memory controller directly connected to the computing device 600) to gain access to the content at the requested memory address(es), the output signal 607 can be sent to the converter 670, which is configured to convert the output signal into an electrical signal comprising the memory address(es). In various examples, the converter 670 may comprise an analog-to-digital converter (ADC). If the output signal 607 is to be sent optically to another entity (e.g., another computing device over an optical interconnect), the output signal 607 can be sent to a laser 660 configured to convert the output into an optical signal to be transmitted to another entity, such as a memory controller or another device.

The optical search engines discussed with respect to FIGS. 1-5B can be implemented within a O-QCAM component of a device (such as computing device 600) to execute various functions, increasing the speed and efficiency of the execution compared to traditional bCAMs and TCAMs with a reduced physical footprint.

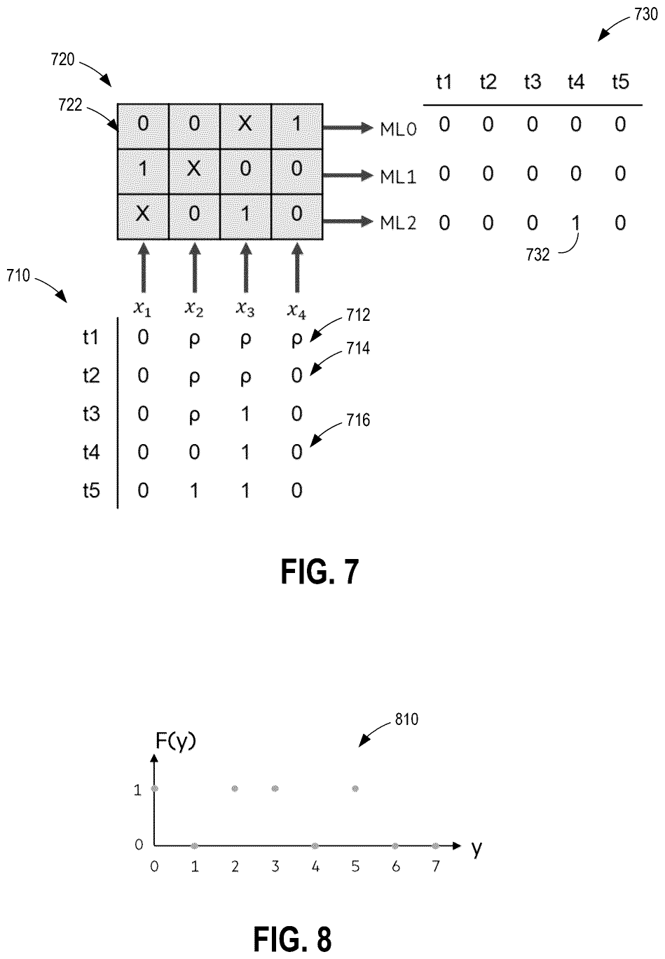

FIG. 7 depicts a schematic representation of an example function-Boolean constrain propagation—that can be executed in accordance with examples of the present disclosure. FIG. 7 includes search words 710 that may be supplied to a search engine programmed with QCAM stored words shown in matrix 720. In examples, the QCAM stored words represented as matrix 720 may be programmed into modulators of any of the search engines described in connection with FIGS. 1-5B, for example, by tuning the tuning components coupled to modulators that make up a particular search engine according to Tables 2 and/or Table 5. The search engine can output results 730 via output routing elements that can be decoded, using Tables 3 and/or Table 6, and used provide a solution to the Boolean constrain propagation. The example of FIG. 7 is provided for illustrative purposes only and should not be interpreted as limiting the scope of the disclosed technology to only the depicted example.

Boolean constraint propagation is a common way to address the solution of Boolean constraints of a particular clause. For example, the QCAM stored words 730 of FIG. 7 may represent the function provided in conjunctive normal form:

$$f = ( {x}_{1} ⋁ {x}_{2} ⋁ ¬ {x}_{4} ) ∧ ( ¬ {x}_{1} ⋁ {x}_{3} ⋁ {x}_{4} ) ∧ ( {x}_{2} ⋁ ¬ {x}_{3} ⋁ {x}_{4} ) \qquad Eq . l$$

Eq. 1 represents a Boolean function where an optical search engine seeks to find values for x₁, x₂, x₃, and x₄ that solve the problem. To solve the problem, f may be set equal to one and in each parenthetical that are clauses. In the example of Eq. 1, there are three clauses, each having inclusive operations or negated operations. For example, in the first clause (e.g., (x₁∨x₂∨¬x₄)), x₁ and x₂ are inclusive and x₄ is negated. The first clause can be mapped to a row of matrix 720 (e.g., row 722), which may be used as a first QCAM stored word. For example, in the case of search engines 312, 412, and 512 the first clause may be used to program the first row. In the case of search engine 212, the first clause may be used to program the first column as a function of time. In this example, a non-negated item (e.g., x₁ and x₂) are represented as a stored data symbol value of logic “0”, negated items (e.g., x₄) are represented as a stored data symbol value of logic “1”, and if the item is not present in the clause (e.g., x₃) the item is represented as a wildcard “X”. The subsequence clauses can be used to program other rows. The O-QCAM can be programed according to Table 2 or Table 5, depending on the implementation.

To perform the Boolean constraint propagation, the search engine receives search words 710 and searches the O-QCAM for a violation (e.g., match) of with the QCAM stored word. Each search word can be encoded by an input encoder (e.g., input encoders 102, 202, 302, 402, and/or 502) according to Tables 1 and/or 4. At a first time step (t1), a first search word 712 is used by an input encoder to generate a first encoded search signal having a logic “0” in a first position and a reject symbol “ρ” in all other positions. The results 730 for the first time step (t1) outputs mismatches on all match lines (ML) (e.g., output from output routing elements). Thus, the output is all logic “0”, which means that none of the clauses is violated.

At each subsequent time step, one of the reject symbols can be replaced with a value symbol of logic “0” or “1”. In the example of FIG. 7, the second search word 714 at the second time step (t2) replaces a reject symbol for x₄ with a logic “0”. Other examples may replace different positions and/or may use logic “1” instead of logic “0”. The second search word 714 is applied to the search engine programmed with matrix 720 to output a corresponding result. In this case, again the result 730 for the second time step represents no violations. This process repeats is repeated until a violation (e.g., a match 732) is located, for example, at the fourth time step (t4) in this example. This means a match (e.g., violation) was located using the fourth search word 716, which means the problem is solved.

In the case of Boolean constraint propagation, the examples herein can be used to locate the change to where a match is located in between at least on clause and a search word. Thus, the reject symbol “ρ” can be beneficial to represent variables that are have not yet been assigned, for example, in the search words 710, and the wildcard symbol “X” can be used for absent for otherwise not involved variables.

As another example, the optical search engines discussed with respect to FIGS. 1-5B can be implemented for any arbitrary Boolean function (F). For example, a search engine in accordance with the above examples can be provided having a number of n O-QCAM cells for implementing an arbitrary Boolean function (F), where the input space contains 2n elements. In the case of a Boolean function (F) over n Boolean variables the number of cells n can be determined as 2⁽ⁿ⁻¹⁾. Thus, in examples, the input space of the Boolean function (F) can be provided as [0:2n−1], such that the function has an interval of integers between 0 and 2n−1. In examples, intervals of the input space can be supplied to an input encoder (e.g., input encoders 102, 202, 302, 402, and/or 502) to encode search words according to Tables 1 and/or 4 and the N O-QCAM cells of the search engine can be driven by driver(s) (e.g., programming controller 106 and/or driver(s) 206, 306, 406, and/or 506) according to Tables 2 and/or 5. The solution to the Boolean function (F) can be output by the search engine and decoded according to Tables 3 and/or 6.

As an illustrative example, FIG. 8 depicts an example Boolean function 810, which is shown as a function of variable y. Boolean function 810 corresponds to an input space of [0:7] and can be implemented in N=4 O-QCAM cells. In this example, Boolean function 810 can be implemented as a row of a search engine. For example, Boolean function 810 can be implemented as four cells in the case of search engines 212, 312, and/or 512 or as one cell in the case of optical search engine 412. Table 7 below provides an example of encoded states that can be programed into example search engines according to Table 2 and/or Table 5 described above.

TABLE 7

cell₀ = 0
cell₁ = X
cell₂ = 1
cell₃ = ρ

Table 8 below provides the example input space where each input integer value represents a search word that can be encoded by an input encoder, according to Tables 1 and/or 4, to generate encoded search signals (e.g., the input encoder may operate to map the encoded inputs symbol values as search words by modulating an input optical signal from an optical source).

TABLE 8

| | |
|---|---|
| Input | Encoded Input |

| integer value | col₀ | col₁ | col₂ | col₃ |
|---|---|---|---|---|
| 0 | 0 | X | X | X |
| 1 | 1 | X | X | X |
| 2 | X | 0 | X | X |
| 3 | X | 1 | X | X |
| 4 | X | X | 0 | X |
| 5 | X | X | 1 | X |
| 6 | X | X | X | 0 |
| 7 | X | X | X | 1 |

Accordingly, as can be seen from the above, the number of cells for implementing the example Boolean function 810 is significantly less than compared to conventional approaches using bCAM and TCAMs. That is, for example, arbitrary Boolean functions performed with bCAM or TCAMs may be limited to n cells, while with O-QCAMs 2n cells can be supported (e.g., a factor of 2). The Boolean function 810 is provided for illustrative purposes only and should not be interpreted as limiting the scope of the disclosed technology to only the depicted example. Other, increasingly more complex or multiple Boolean functions may be implemented in the examples disclosed herein. Thus, the benefits demonstrated by the above example may be increasingly impactful as the complexity of the Boolean function(s) implemented increases.

As another example, the optical search engines discussed with respect to FIGS. 1-5B can be implemented for equality check. For example, a search engine in accordance with the above examples can be provided having a number of n O-QCAM cells that can be implemented to execute an equality check over

$$[ 0 : ( \begin{matrix}2 n \\ n\end{matrix} ) - 1 ]$$

intervals of input space. Whereas, bCAM and TCAM based search engines may be able to execute an equality check over 2n intervals of input space.

As an illustrative example, in the search engines discussed with respect to FIGS. 1-5B, three O-QCAM cells (e.g., n=3) can be implemented to perform an equality check over 20 intervals, whereas bCAM and TCAM may only be able to check 8 intervals. Table 9 below provides an example of an equality check over 20 intervals, (e.g., rows [0:19]). The encoded search symbols values of the interval input space can be shown in Table 9 can be supplied to an input encoder (e.g., input encoders 102, 202, 302, 402, and/or 502) to encode search words according to Tables 1 and/or 4. The encoded QCAM data symbol values can be programmed into three O-QCAM cells by driver(s) (e.g., programming controller 106 and/or driver(s) 206, 306, 406, and/or 506) according to Tables 2 and/or 5. As shown in Table 9, the number of wildcard symbols “X” is equal to the number of a reject symbols “ρ” in each row. This is because, in the examples disclosed herein, the reject symbol “ρ” can be used to search a wildcard symbol “X” in the input encoding and the wildcard symbol “X” can be used to search a reject symbol “ρ”.

TABLE 9

| | Encoded Search Symbol | | | Encoded QCAM Data | | |
|---|---|---|---|---|---|---|
| | Value | | | Symbol Value | | |
| | Column 3 | Column 2 | Column 1 | Cell 3 | Cell 2 | Cell 1 |
| 0 | 0 | 0 | 0 | 0 | 0 | 0 |
| 1 | 0 | 0 | 1 | 0 | 0 | 1 |
| 2 | 0 | 1 | 0 | 0 | 1 | 0 |
| 3 | 0 | 1 | 1 | 0 | 1 | 1 |
| 4 | 1 | 0 | 0 | 1 | 0 | 0 |
| 5 | 1 | 0 | 1 | 1 | 0 | 1 |
| 6 | 1 | 1 | 0 | 1 | 1 | 0 |
| 7 | 1 | 1 | 1 | 1 | 1 | 1 |
| 8 | 0 | X | ρ | 0 | ρ | X |
| 9 | 0 | ρ | X | 0 | X | ρ |
| 10 | X | 0 | ρ | ρ | 0 | X |
| 11 | X | ρ | 0 | ρ | X | 0 |
| 12 | ρ | 0 | X | X | 0 | ρ |
| 13 | ρ | X | 0 | X | ρ | 0 |
| 14 | 1 | X | ρ | 1 | ρ | X |
| 15 | 1 | ρ | X | 1 | X | ρ |
| 16 | X | 1 | ρ | ρ | 1 | X |
| 17 | X | ρ | 1 | ρ | X | 1 |
| 18 | ρ | 1 | X | X | 1 | ρ |
| 19 | ρ | X | 1 | X | ρ | 1 |

The requests of the example equality check are shown in Table 10 below, which can be output by the search engine and decoded according to Tables 3 and/or 6. Each search symbol value of Table 9 is compared to each QCAM data symbol value of Table 9 to provide the below results. In the below example, each True “T” represents a match result, for example, no light on an output routing element of the search engine and each False “F” represents a mismatch. For example, the results of the equality check of the search symbol value for interval 8 (e.g., row 9) in Table 9 compared to the QCAM data symbol value of interval 8 is True “T” (e.g., s₈·d₈=[0,1,0,0,1,1]·[1,0,1,1,0,0]=0, based on the encoding scheme of Tables 1 and 2 and/or Tables 4 and 5), which can be represented as no light output by the search engines described in the connection with FIGS. 1-5B. Whereas, the results of the equality check of the search symbol value for interval 8 (e.g., row 9) in Table 9 compared to the QCAM data symbol value of interval 10 is False “F” (e.g., s₈·d₁₀=[0,1,0,0,1,1]·[1,1,1,0,0,0]=1, based on the encoding scheme of Tables 1 and 2 and/or Tables 4 and 5), which can be represented as light output by the search engines described in the connection with FIGS. 1-5B.

TABLE 10

| | | QCAM Symbol Value | | | | | | | | | | | | | | | | | | | |
|---|---|---|---|---|---|---|---|---|---|---|---|---|---|---|---|---|---|---|---|---|---|
| | | 0 | 1 | 2 | 3 | 4 | 5 | 6 | 7 | 8 | 9 | 10 | 11 | 12 | 13 | 14 | 15 | 16 | 17 | 18 | 19 |
| Search | 0 | T | F | F | F | F | F | F | F | F | F | F | F | F | F | F | F | F | F | F | F |
| Symbol | 1 | F | T | F | F | F | F | F | F | F | F | F | F | F | F | F | F | F | F | F | F |
| Value | 2 | F | F | T | F | F | F | F | F | F | F | F | F | F | F | F | F | F | F | F | F |
| | 3 | F | F | F | T | F | F | F | F | F | F | F | F | F | F | F | F | F | F | F | F |
| | 4 | F | F | F | F | T | F | F | F | F | F | F | F | F | F | F | F | F | F | F | F |
| | 5 | F | F | F | F | F | T | F | F | F | F | F | F | F | F | F | F | F | F | F | F |
| | 6 | F | F | F | F | F | F | T | F | F | F | F | F | F | F | F | F | F | F | F | F |
| | 7 | F | F | F | F | F | F | F | T | F | F | F | F | F | F | F | F | F | F | F | F |
| | 8 | F | F | F | F | F | F | F | F | T | F | F | F | F | F | F | F | F | F | F | F |
| | 9 | F | F | F | F | F | F | F | F | F | T | F | F | F | F | F | F | F | F | F | F |
| | 10 | F | F | F | F | F | F | F | F | F | F | T | F | F | F | F | F | F | F | F | F |
| | 11 | F | F | F | F | F | F | F | F | F | F | F | T | F | F | F | F | F | F | F | F |
| | 12 | F | F | F | F | F | F | F | F | F | F | F | F | T | F | F | F | F | F | F | F |
| | 13 | F | F | F | F | F | F | F | F | F | F | F | F | F | T | F | F | F | F | F | F |
| | 14 | F | F | F | F | F | F | F | F | F | F | F | F | F | F | T | F | F | F | F | F |
| | 15 | F | F | F | F | F | F | F | F | F | F | F | F | F | F | F | T | F | F | F | F |
| | 16 | F | F | F | F | F | F | F | F | F | F | F | F | F | F | F | F | T | F | F | F |
| | 17 | F | F | F | F | F | F | F | F | F | F | F | F | F | F | F | F | F | T | F | F |
| | 18 | F | F | F | F | F | F | F | F | F | F | F | F | F | F | F | F | F | F | T | F |
| | 19 | F | F | F | F | F | F | F | F | F | F | F | F | F | F | F | F | F | F | F | T |

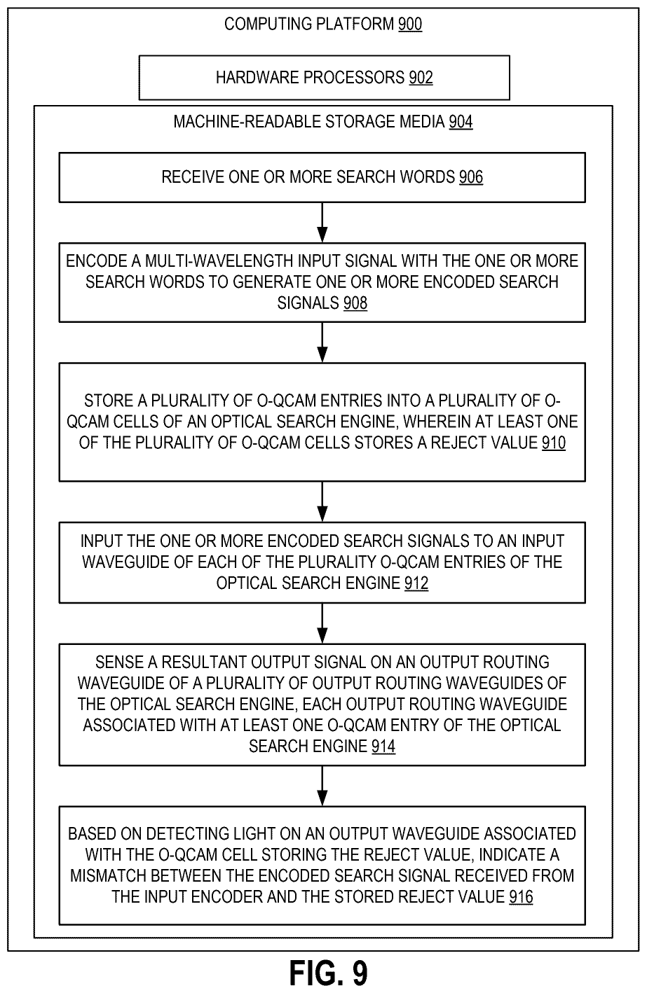

FIG. 9 illustrates a computing component that may be used to implement the optical search engines in accordance with various examples of the disclosed technology. Referring now to FIG. 9, computing component 900 may be, for example, a server computer, a controller, or any other similar computing component capable of processing data. In the example implementation of FIG. 9, the computing component 900 includes a hardware processor 902, and machine-readable storage medium 904.

Hardware processor 902 may be one or more central processing units (CPUs), semiconductor-based microprocessors, and/or other hardware devices suitable for retrieval and execution of instructions stored in machine-readable storage medium 904. Hardware processor 902 may fetch, decode, and execute instructions, such as instructions 906-916, to control processes or operations optical search engines described in accordance with the examples in FIGS. 1-5B. As an alternative or in addition to retrieving and executing instructions, hardware processor 902 may include one or more electronic circuits that include electronic components for performing the functionality of one or more instructions, such as a field programmable gate array (FPGA), application specific integrated circuit (ASIC), or other electronic circuits.

A machine-readable storage medium, such as machine-readable storage medium 904, may be any electronic, magnetic, optical, or other physical storage device that contains or stores executable instructions. Thus, machine-readable storage medium 904 may be, for example, Random Access Memory (RAM), non-volatile RAM (NVRAM), an Electrically Erasable Programmable Read-Only Memory (EEPROM), a storage device, an optical disc, and the like. In some examples, machine-readable storage medium 904 may be a non-transitory storage medium, where the term “non-transitory” does not encompass transitory propagating signals. As described in detail below, machine-readable storage medium 904 may be encoded with executable instructions, for example, instructions 906-916.

Hardware processor 902 may execute instruction 906 to receive one or more search words. For example, one or more search words can be received by an input encoder (e.g., one of input encoders 102, 202, 302, 402, and/or 502 of FIGS. 1, 2A, 3A, 4A, and 5A).

Hardware processor 902 may execute instruction 908 to encode a multi-wavelength input signal with the one or more search words to generate one or more encoded search signals. For example, the input encoder may encode multi-wavelength input signals with the one or more search words to generate encoded search signals, such as, for example, encoded search signals 110, 210A-210K, 310A-310M, 410A-410M, and/or 510A-510M as described in connection with FIGS. 1, 2A, 3A, 4A, and 5A. In examples, each bit position of a search word of the one or more search words can be encoded as an amplitude, a wavelength, or a combination of both.

Hardware processor 902 may execute instruction 910 to store a plurality of O-QCAM entries into a plurality of O-QCAM cells of an optical search engine. In examples, at least one of the plurality of O-QCAM cells stores a reject value (e.g., a “ρ”). In examples, a program controller (e.g., program controller 106 of FIG. 1) and/or driver(s) (e.g., driver(s) 206, 306, 406, and/or 506) can receive, from a word storage (e.g., QCAM word storage 108, 308 and/or 408) at least one word to be stored as an O-QCAM entry of the plurality of O-QCAM entries. The at least one word, in examples, can comprise a plurality of bits. The program controller/driver(s) can be operated to store a bit value for each bit of the plurality of bits within an O-QCAM cell of the plurality of O-QCAM cells of the O-QCAM entry.

The plurality of O-QCAM cells may constitute the optical search engine (e.g., search engine 100, 200, 300, 400, and/or 500). Each O-QCAM cell may be implemented as one or more modulators (e.g., modulators 101, 201, 301, 401, and/or 501) that can be implemented to store a symbol value, such as logic ‘0’, logic ‘1’, a wildcard symbol ‘X’, or a reject value ‘ρ’. In examples, the program controller/driver(s) can be operated to tune modulators of an optical search engine to represent bits of each QCAM word, for example, as described above in connection with FIGS. 1-5B. In examples, each bit position of an O-QCAM entry can be encoded as an amplitude, a wavelength, or a combination of both.

For example, an O-QCAM cell, in some examples, may be configured to represent a reject value when a first modulator is tuned (e.g., by the program controller/driver(s)) to pass light of a first wavelength of a bit position-specific set of wavelengths and a second modulator is tuned to pass light of a second wavelength of the bit position-specific set of wavelengths. The O-QCAM cell may be configured to represent a logic ‘0’, for example, when the first modulator is tuned to pass light of the first wavelength of the bit position-specific set of wavelengths and the second modulator is tuned to block light of the second wavelength of the bit position-specific set of wavelengths. The O-QCAM cell may be configured to represent a logic ‘1’, for example, when the first modulator is tuned to block light of the first wavelength of the bit position-specific set of wavelengths and the second modulator is tuned to pass light of the second wavelength of the bit position-specific set of wavelengths. The O-QCAM cell can be configured to represent a wildcard value, for example, when the first modulator is tuned to block light of the first wavelength of the bit position-specific set of wavelengths and the second modulator is tuned to block light of the second wavelength of the bit position-specific set of wavelengths.

In another example, each O-QCAM cell may comprise a first modulator. In this example, the O-QCAM cell can be configured to represent a reject value when the first modulator is tuned to pass light of a first wavelength during a first time slot and during a second time slot. The O-QCAM cell, in this example, can be configured to represent a logic ‘0’ when the first modulator is tuned to pass light of the first wavelength during a first time slot and the first modulator is tuned to block light of the first wavelength during a second time slot. The O-QCAM cell, in this example, can be configured represents a logic ‘1’ when the first modulator is tuned to block light of the first wavelength during a first time slot and the first modulator is tuned to block light of the first wavelength during a second time slot. The O-QCAM cell, in this example, can be configured to represent a wildcard value when the first modulator is tuned to block light of the first wavelength during a first time slot and during a second time slot.

Hardware processor 902 may execute instruction 912 to input the one or more encoded search signals to an input waveguide of each of the plurality O-QCAM entries of the optical search engine. For example, the input encoder may couple the encoded search signals to input waveguides, such as input waveguides 104, 204A-204K, 304A-304M, 404A-404M, and/or 504A-504M, that couple the encoded search signals to the optical search engine, as described above in connection with FIGS. 1-5B.

Hardware processor 902 may execute instruction 914 to sense, by a plurality of photodetectors, a resultant output signal on an output routing waveguide of a plurality of output routing waveguides of the optical search engine. Each output routing waveguide can be associated with at least one O-QCAM entry of the optical search engine. For example, photodetectors (e.g., photodetectors 109, 209A-A through 209M-K, 309A-309M, 409A-409K, and/or 509A-509B) can detect resultant output signals from the optical search engine and provide an indication of a match or mismatch based on the resultant output signal, as described above in connection with FIGS. 1-5B.

Hardware processor 902 may execute instruction 916, based on detecting light on an output waveguide associated with the O-QCAM cell storing the reject value, indicating, by the respective photodetector, a mismatch between the encoded search signals received from the input encoder and the stored reject value.

In examples, the optical search engine can be programmed to execute one or more functions. For example, the optical search engine can be programmed to execute Boolean constrain propagation, as described above in connection with FIG. 7. In this example, a conjunctive normal form of a function comprises a plurality of clauses and each clause can be mapped to a QCAM word entry of the plurality of QCAM word entries. In another example, the optical search engine can be programmed to execute a Boolean function comprising 2n−1 input integers mapped to the plurality of QCAM word entries, for example, as described above in connection with FIG. 8. In another example, the optical search engine can be programmed to execute an equality check comprising

$$[ 0 : ( \begin{matrix}2 n \\ n\end{matrix} ) - 1 ]$$

input entries mapped to the plurality of QCAM word entries. In the above examples, n may represent the number of O-QCAM cells in the plurality of O-QCAM cells.

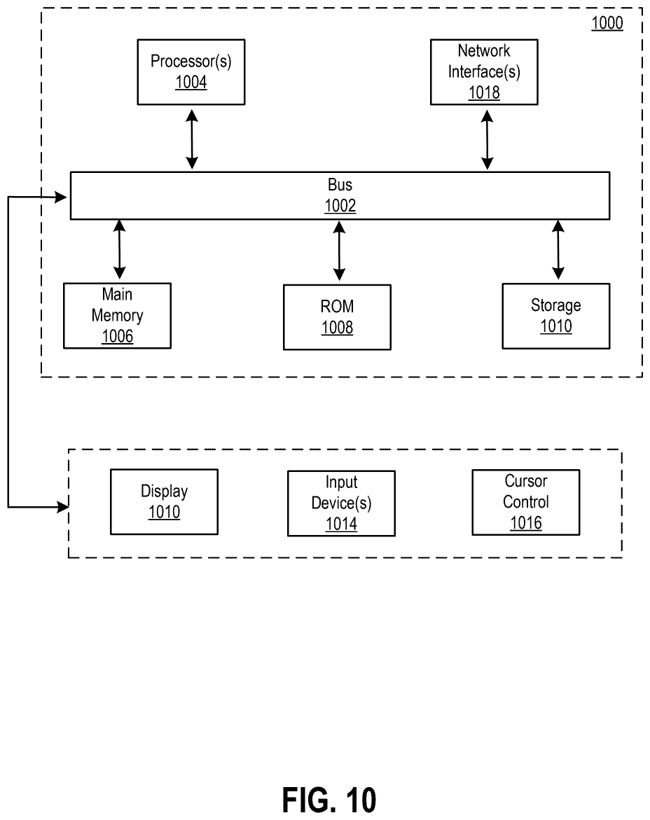

FIG. 10 depicts a block diagram of an example computer system 1000 in which various examples of the disclosed technology described herein may be implemented. The computer system 1000 includes a bus 1002 or other communication mechanism for communicating information, one or more hardware processors 1004 coupled with bus 1002 for processing information. Hardware processor(s) 1004 may be, for example, one or more general purpose microprocessors. The computer system 10000 may be implemented as one or more component of the optical search engines described in connection with FIGS. 1-5B, for example, input encoders, programming controller or driver(s), QCAM word storage, etc.

The computer system 1000 also includes a main memory 1006, such as a random access memory (RAM), cache and/or other dynamic storage devices, coupled to bus 1002 for storing information and instructions to be executed by processor 1004. Main memory 1006 also may be used for storing temporary variables or other intermediate information during execution of instructions to be executed by processor 1004. Such instructions, when stored in storage media accessible to processor 1004, render computer system 1000 into a special-purpose machine that is customized to perform the operations specified in the instructions. For example, main memory 1006 may store instructions, that when executed by processor(s) 1004, cause computer system 1000 to perform one or more of the operations described in connection with FIG. 9.

The computer system 1000 further includes a read only memory (ROM) 1008 or other static storage device coupled to bus 1002 for storing static information and instructions for processor 1004. A storage device 1010, such as a magnetic disk, optical disk, or USB thumb drive (Flash drive), etc., is provided and coupled to bus 1002 for storing information and instructions.

The computer system 1000 may be coupled via bus 1002 to a display 1012, such as a liquid crystal display (LCD) (or touch screen), for displaying information to a computer user. An input device 1014, including alphanumeric and other keys, is coupled to bus 1002 for communicating information and command selections to processor 1004. Another type of user input device is cursor control 1016, such as a mouse, a trackball, or cursor direction keys for communicating direction information and command selections to processor 1004 and for controlling cursor movement on display 1012. In some examples, the same direction information and command selections as cursor control may be implemented via receiving touches on a touch screen without a cursor.

The computing system 1000 may include a user interface module to implement a GUI that may be stored in a mass storage device as executable software codes that are executed by the computing device(s). This and other modules may include, by way of example, components, such as software components, object-oriented software components, class components and task components, processes, functions, attributes, procedures, subroutines, segments of program code, driver(s), firmware, microcode, circuitry, data, databases, data structures, tables, arrays, and variables.

In general, the word “component,” “engine,” “system,” “database,” data store,” and the like, as used herein, can refer to logic embodied in hardware or firmware, or to a collection of software instructions, possibly having entry and exit points, written in a programming language, such as, for example, Java, C or C++. A software component may be compiled and linked into an executable program, installed in a dynamic link library, or may be written in an interpreted programming language such as, for example, BASIC, Perl, or Python. It will be appreciated that software components may be callable from other components or from themselves, and/or may be invoked in response to detected events or interrupts. Software components configured for execution on computing devices may be provided on a computer readable medium, such as a compact disc, digital video disc, flash drive, magnetic disc, or any other tangible medium, or as a digital download (and may be originally stored in a compressed or installable format that requires installation, decompression or decryption prior to execution). Such software code may be stored, partially or fully, on a memory device of the executing computing device, for execution by the computing device. Software instructions may be embedded in firmware, such as an EPROM. It will be further appreciated that hardware components may be comprised of connected logic units, such as gates and flip-flops, and/or may be comprised of programmable units, such as programmable gate arrays or processors.

The computer system 1000 may implement the techniques described herein using customized hard-wired logic, one or more ASICs or FPGAS, firmware and/or program logic which in combination with the computer system causes or programs computer system 1000 to be a special-purpose machine. According to one example of the disclosed technology, the techniques herein are performed by computer system 1000 in response to processor(s) 1004 executing one or more sequences of one or more instructions contained in main memory 1006. Such instructions may be read into main memory 1006 from another storage medium, such as storage device 1010. Execution of the sequences of instructions contained in main memory 1006 causes processor(s) 1004 to perform the process steps described herein. In alternative examples, hard-wired circuitry may be used in place of or in combination with software instructions.

The term “non-transitory media,” and similar terms, as used herein refers to any media that store data and/or instructions that cause a machine to operate in a specific fashion. Such non-transitory media may comprise non-volatile media and/or volatile media. Non-volatile media includes, for example, optical or magnetic disks, such as storage device 1010. Volatile media includes dynamic memory, such as main memory 1006. Common forms of non-transitory media include, for example, a floppy disk, a flexible disk, hard disk, solid state drive, magnetic tape, or any other magnetic data storage medium, a CD-ROM, any other optical data storage medium, any physical medium with patterns of holes, a RAM, a PROM, and EPROM, a FLASH-EPROM, NVRAM, any other memory chip or cartridge, and networked versions of the same.

Non-transitory media is distinct from but may be used in conjunction with transmission media. Transmission media participates in transferring information between non-transitory media. For example, transmission media includes coaxial cables, copper wire and fiber optics, including the wires that comprise bus 1002. Transmission media can also take the form of acoustic or light waves, such as those generated during radio-wave and infra-red data communications.

The computer system 1000 also includes a network interface 1018 (also referred to as a communication interface) coupled to bus 1002. Network interface 1018 provides a two-way data communication coupling to one or more network links that are connected to one or more local networks. For example, network interface 1018 may be an integrated services digital network (ISDN) card, cable modem, satellite modem, or a modem to provide a data communication connection to a corresponding type of telephone line. As another example, network interface 1018 may be a local area network (LAN) card to provide a data communication connection to a compatible LAN (or WAN component to communicated with a WAN). Wireless links may also be implemented. In any such implementation, network interface 1018 sends and receives electrical, electromagnetic or optical signals that carry digital data streams representing various types of information.

A network link typically provides data communication through one or more networks to other data devices. For example, a network link may provide a connection through local network to a host computer or to data equipment operated by an Internet Service Provider (ISP). The ISP in turn provides data communication services through the world wide packet data communication network now commonly referred to as the “Internet.” Local network and Internet both use electrical, electromagnetic or optical signals that carry digital data streams. The signals through the various networks and the signals on network link and through network interface 1018, which carry the digital data to and from computer system 1000, are example forms of transmission media.

The computer system 1000 can send messages and receive data, including program code, through the network(s), network link and network interface 1018. In the Internet example, a server might transmit a requested code for an application program through the Internet, the ISP, the local network and the network interface 1018.

The received code may be executed by processor 1004 as it is received, and/or stored in storage device 1010, or other non-volatile storage for later execution.

Each of the processes, methods, and algorithms described in the preceding sections may be embodied in, and fully or partially automated by, code components executed by one or more computer systems or computer processors comprising computer hardware. The one or more computer systems or computer processors may also operate to support performance of the relevant operations in a “cloud computing” environment or as a “software as a service” (SaaS). The processes and algorithms may be implemented partially or wholly in application-specific circuitry. The various features and processes described above may be used independently of one another, or may be combined in various ways. Different combinations and sub-combinations are intended to fall within the scope of this disclosure, and certain method or process blocks may be omitted in some implementations. The methods and processes described herein are also not limited to any particular sequence, and the blocks or states relating thereto can be performed in other sequences that are appropriate, or may be performed in parallel, or in some other manner. Blocks or states may be added to or removed from the disclosed examples. The performance of certain of the operations or processes may be distributed among computer systems or computers processors, not only residing within a single machine, but deployed across a number of machines.

As used herein, a circuit might be implemented utilizing any form of hardware, software, or a combination thereof. For example, one or more processors, controllers, ASICs, PLAS, PALs, CPLDs, FPGAs, logical components, software routines or other mechanisms might be implemented to make up a circuit. In implementation, the various circuits described herein might be implemented as discrete circuits or the functions and features described can be shared in part or in total among one or more circuits. Even though various features or elements of functionality may be individually described or claimed as separate circuits, these features and functionality can be shared among one or more common circuits, and such description shall not require or imply that separate circuits are required to implement such features or functionality. Where a circuit is implemented in whole or in part using software, such software can be implemented to operate with a computing or processing system capable of carrying out the functionality described with respect thereto, such as computer system 1000.

As used herein, the term “or” may be construed in either an inclusive or exclusive sense. Moreover, the description of resources, operations, or structures in the singular shall not be read to exclude the plural. Conditional language, such as, among others, “can,” “could,” “might,” or “may,” unless specifically stated otherwise, or otherwise understood within the context as used, is generally intended to convey that certain examples include, while other examples do not include, certain features, elements and/or steps.

Terms and phrases used in this document, and variations thereof, unless otherwise expressly stated, should be construed as open ended as opposed to limiting. Adjectives such as “conventional,” “traditional,” “normal,” “standard,” “known,” and terms of similar meaning should not be construed as limiting the item described to a given time period or to an item available as of a given time, but instead should be read to encompass conventional, traditional, normal, or standard technologies that may be available or known now or at any time in the future. The presence of broadening words and phrases such as “one or more,” “at least,” “but not limited to” or other like phrases in some instances shall not be read to mean that the narrower case is intended or required in instances where such broadening phrases may be absent.

What is claimed is:

1. An optical quaternary content addressable memory (O-QCAM) comprising:
a search input configured to convert a multi-wavelength input signal encoded with a search word into a plurality of search optical signals;
a plurality of QCAM word entries, each QCAM word entry comprising a plurality of O-QCAM cells; and
a plurality of photodetectors, each photodetector optically coupled to a results end of a respective output match waveguide of an QCAM word entry,
wherein each O-QCAM cell is configured to store a reject value and one or more of:
a logic ‘0’;
a logic ‘1’; and
a wildcard value.

2. The O-QCAM of claim 1, wherein each photodetector is configured to detect a mismatch between a respective search optical signal and a respective O-QCAM entry by detecting light of at least one wavelength of the multi-wavelength input signal.

3. The O-QCAM of claim 2, wherein, when the respective O-QCAM entry stores the reject value, each photodetector detects the mismatch between the respective search optical signal and the respective O-QCAM entry for any value of the respective search optical signal other than a wildcard value.

4. The O-QCAM of claim 1, wherein each QCAM word entry comprises:
an input waveguide configured to optically couple to one of a plurality of search optical signals; and
an output match waveguide.

5. The O-QCAM of claim 4, wherein each O-QCAM cell comprises one or more modulators disposed between the input waveguide and the output match waveguide.

6. The optical O-QCAM of claim 1, wherein each O-QCAM cell comprises a set of modulators comprising a first modulator and a second modulator.

7. The optical O-QCAM of claim 6, wherein:
an O-QCAM cell represents a reject value when the first modulator is tuned to pass light of a first wavelength of a bit position-specific set of wavelengths and the second modulator is tuned to pass light of a second wavelength of the bit position-specific set of wavelengths;
an O-QCAM cell represents a logic ‘0’ when the first modulator is tuned to pass light of the first wavelength of the bit position-specific set of wavelengths and the second modulator is tuned to block light of the second wavelength of the bit position-specific set of wavelengths;
an O-QCAM cell represents a logic ‘1’ when the first modulator is tuned to block light of the first wavelength of the bit position-specific set of wavelengths and the second modulator is tuned to pass light of the second wavelength of the bit position-specific set of wavelengths; and
an O-QCAM cell represents a wildcard value when the first modulator is tuned to block light of the first wavelength of the bit position-specific set of wavelengths and the second modulator is tuned to block light of the second wavelength of the bit position-specific set of wavelengths.

8. The optical O-QCAM of claim 1, wherein each O-QCAM cell comprises a first modulator, wherein:
an O-QCAM cell represents a reject value when the first modulator is tuned to pass light of a first wavelength during a first time slot and during a second time slot;
an O-QCAM cell represents a logic ‘0’ when the first modulator is tuned to pass light of the first wavelength during a first time slot and the first modulator is tuned to block light of the first wavelength during a second time slot;
an O-QCAM cell represents a logic ‘1’ when the first modulator is tuned to block light of the first wavelength during a first time slot and the first modulator is tuned to block light of the first wavelength during a second time slot; and
an O-QCAM cell represents a wildcard value when the first modulator is tuned to block light of the first wavelength during a first time slot and during a second time slot.

9. The optical O-QCAM of claim 1, wherein O-QCAM is configured to execute Boolean constrain propagation, wherein a conjunctive normal form of a function comprises a plurality of clauses, wherein each clause is mapped to a QCAM word entry of the plurality of QCAM word entries.

10. The optical O-QCAM of claim 1, wherein the O-QCAM is configured to execute a Boolean function comprising 2n−1 input integers mapped to the plurality of search optical signals, wherein n is a number of O-QCAM cells in the plurality of O-QCAM cells.

11. The optical O-QCAM of claim 1, wherein the O-QCAM is configured to execute an equality check comprising
$$[ 0 : ( \begin{matrix}2 n \\ n\end{matrix} ) - 1 ]$$
input entries mapped to the plurality of search optical signals, wherein n is the number of O-QCAM cells in the plurality of O-QCAM cells.

12. A method, comprising:
receiving, by an input encoder, one or more search words;
encoding, by the input encoder, a multi-wavelength input signal with the one or more search words to generate one or more encoded search signals;
storing, by a programming controller, a plurality of optical quaternary content addressable memory (O-QCAM) entries into a plurality of O-QCAM cells of an optical search engine, wherein at least one of the plurality of O-QCAM cells stores a reject value;
inputting, by the input encoder, the one or more encoded search signals to an input waveguide of each of the plurality O-QCAM entries of the optical search engine;
sensing, by a plurality of photodetectors, a resultant output signal on an output routing waveguide of a plurality of output routing waveguides of the optical search engine, each output routing waveguide associated with at least one O-QCAM entry of the optical search engine; and
based on detecting light on an output waveguide associated with the O-QCAM cell storing the reject value, indicating, by the respective photodetector, a mismatch between the encoded search signal received from the input encoder and the stored reject value.

13. The method of claim 12, wherein each bit position of an O-QCAM entry and each bit position of a search word of the one or more search words are encoded as an amplitude, a wavelength, or a combination of both.

14. The method of claim 12, further comprising:
receiving, by the programming controller, at least one word to be stored in a O-QCAM entry of the plurality of O-QCAM entries, the at least one word comprising a plurality of bits; and
storing, by the programming controller, a bit value for each bit of the plurality of bits within a O-QCAM cell of the plurality of O-QCAM cells of the O-QCAM entry.

15. The method of claim 14, wherein each O-QCAM cell comprises a set of optical modulators, wherein:
an O-QCAM cell represents a reject value when a first optical modulator of the set of optical modulators is tuned to pass light of a first wavelength of a bit position-specific set of wavelengths and a second modulator is tuned to pass light of a second wavelength of the bit position-specific set of wavelengths;
an O-QCAM cell represents a logic ‘0’ when the first modulator is tuned to pass light of the first wavelength of the bit position-specific set of wavelengths and the second modulator is tuned to block light of the second wavelength of the bit position-specific set of wavelengths;
an O-QCAM cell represents a logic ‘1’ when the first modulator is tuned to block light of the first wavelength of the bit position-specific set of wavelengths and the second modulator is tuned to pass light of the second wavelength of the bit position-specific set of wavelengths; and
an O-QCAM cell represents a wildcard value when the first modulator is tuned to block light of the first wavelength of the bit position-specific set of wavelengths and the second modulator is tuned to block light of the second wavelength of the bit position-specific set of wavelengths.

16. The method of claim 14, wherein each O-QCAM cell comprises a first modulator, wherein:
an O-QCAM cell represents a reject value when the first modulator is tuned to pass light of a first wavelength during a first time slot and during a second time slot;
an O-QCAM cell represents a logic ‘0’ when the first modulator is tuned to pass light of the first wavelength during a first time slot and the first modulator is tuned to block light of the first wavelength during a second time slot;
an O-QCAM cell represents a logic ‘1’ when the first modulator is tuned to block light of the first wavelength during a first time slot and the first modulator is tuned to block light of the first wavelength during a second time slot; and
an O-QCAM cell represents a wildcard value when the first modulator is tuned to block light of the first wavelength during a first time slot and during a second time slot.

17. The method of claim 12, wherein the optical search engine is programmed, by the programming controller, to execute at least one of:
Boolean constrain propagation, wherein a conjunctive normal form of a function comprises a plurality of clauses, wherein each clause is mapped to a QCAM word entry of the plurality of O-QCAM word entries;
a Boolean function comprising 2n−1 input integers mapped to the plurality of O-QCAM word entries; and
an equality check comprising
$$[ 0 : ( \begin{matrix}2 n \\ n\end{matrix} ) - 1 ]$$
input entries mapped to the plurality of O-QCAM word entries,
wherein n is a number of O-QCAM cells in the plurality of O-QCAM cells.

18. An optical quaternary content addressable memory (O-QCAM), comprising:
an input encoder configured to input encoded optical signals representative of one or more search words from a search word source;
an optical search engine optically coupled to the input encoder, the optical search engine comprising a plurality of O-QCAM cells configured to store a plurality of QCAM stored words; and
a photodetector array comprising a plurality of photodetectors optically coupled to a plurality of output routing waveguides of the optical search engine, each photodetector of the photodetector array associated with an output routing waveguide of the plurality of output waveguides,
wherein the optical search engine is configured to pass an input encoded optical signal corresponding to a bit position of an input search word to an output routing waveguide to indicate a mismatch between a bit the search word and a bit of a O-QCAM stored word irrespective the input encoded optical signal.

19. The O-QCAM of claim 18, wherein each O-QCAM cell comprises one or more modulators disposed between an input waveguide and the output match waveguide, the O-QCAM further comprising:
a programming controller configured to store the plurality of QCAM stored words to respective O-QCAM cells by tuning the one or more modulators of the plurality of O-QCAM cells.

20. The O-QCAM of claim 19, wherein passing the input encoded optical signal comprising storing a reject value in an O-QCAM cell corresponding to the O-QCAM stored word.
